(19) United States
(12) Patent Application Publication
(10) Pub. No.: US 2025/0234717 A1
(43) Pub. Date: Jul. 17, 2025

(54) DISPLAY PANEL AND DISPLAY DEVICE

(71) Applicants: Hefei Visionox Technology Co., Ltd., Hefei (CN); Visionox Technology Inc., Jiangsu (CN)

(72) Inventors: Jian DENG, Hefei (CN); Yuanjiang HUANG, Hefei (CN); Lei ZHANG, Hefei (CN); Yuan YAO, Hefei (CN); Bo RAO, Hefei (CN)

(73) Assignees: Hefei Visionox Technology Co., Ltd., Hefei (CN); Visionox Technology Inc., Jiangsu (CN)

(21) Appl. No.: 18/940,023

(22) Filed: Nov. 7, 2024

Related U.S. Application Data
(63) Continuation of application No. PCT/CN2024/102785, filed on Jun. 30, 2024.

(30) Foreign Application Priority Data
Jan. 15, 2024 (CN) 202410053962.7
Jan. 19, 2024 (CN) 202410081303.4

(51) Int. Cl. H10K 59/122; G06F 3/041; H10K 59/35; H10K 59/40

(52) U.S. Cl. CPC H10K 59/122; G06F 3/0412; H10K 59/353; H10K 59/40; G06F 2203/04112

(57) ABSTRACT

A display panel and a display device. The display panel includes an array substrate, an isolation structure, a light emitting function layer, and a touch layer. The isolation structure is disposed on a side of the array substrate, and the isolation structure is provided with a plurality of isolation openings and a plurality of first openings; the light emitting function layer includes a plurality of light emitting units, at least a part of the light emitting unit is disposed within the isolation opening; the touch layer is disposed on a side of the isolation structure away from the array substrate, the touch layer includes one or more touch wirings, an orthographic projection of the touch wiring on the array substrate is located within an orthographic projection of the isolation structure on the array substrate.

### CROSS-REFERENCE TO RELATED APPLICATION

The present application is a continuation application of International Application No. PCT/CN2024/102785, filed on Jun. 30, 2024, and titled “DISPLAY PANEL AND DISPLAY DEVICE”, which claims priority to Chinese Patent Application No. 202410053962.7, filed on Jan. 15, 2024, and titled “DISPLAY PANEL, METHOD FOR MANUFACTURING DISPLAY PANEL, AND ELECTRONIC DEVICE”, and Chinese Patent Application No. 202410081303.4, filed on Jan. 19, 2024, and titled “DISPLAY PANEL AND DISPLAY DEVICE”, all of which are hereby incorporated by reference in their entireties.

### TECHNICAL FIELD

The present application relates to the technical field of display device, and particularly to a display panel and a display device.

### BACKGROUND

Liquid Crystal Display (LCD) panels, Organic Light Emitting Diode (OLED) display panels, and display panels using Light Emitting Diode (LED) devices are widely used in cell phones, TVs, personal digital assistants, digital cameras, notebook computers, desktop computers and other consumer electronic products due to their high image quality, power saving, thin body and wide range of applications.

In the related art, a light sensor is disposed on a side of the display panel. The light sensor can receive the light passing through the display panel, and the light transmittance of the display panel is poor, which affects the recognition accuracy of the light sensor.

### SUMMARY

Embodiments of the present application provide a display panel and a display device, which are designed to improve the light transmittance of the display panel.

In a first aspect, the embodiments of the present application provide a display panel, including:
an array substrate;
an isolation structure disposed on a side of the array substrate, the isolation structure being provided with a plurality of isolation openings and a plurality of first openings;
a light emitting function layer including a plurality of light emitting units, at least a part of the light emitting unit being disposed within the isolation opening;
a touch layer disposed on a side of the isolation structure away from the array substrate, the touch layer including one or more touch wirings, an orthographic projection of the touch wiring on the array substrate being located within an orthographic projection of the isolation structure on the array substrate, an orthographic projection of the touch wiring on the isolation structure being a first projection, and the first projection surrounding a part of a boundary of at least one of the first openings.

In a second aspect, the embodiments of the present application provide a display panel, including:
an array substrate;
an isolation structure disposed on a side of the array substrate, the isolation structure enclosing and forming a plurality of isolation openings, and the isolation structure being provided with a plurality of first openings;
a light emitting function layer including a plurality of light emitting units, at least a part of the light emitting unit being disposed within the isolation opening;
a touch layer disposed on a side of the isolation structure away from the array substrate, the touch layer including one or more touch wirings, an orthographic projection of the touch wiring on the array substrate being located within an orthographic projection of the isolation structure on the array substrate, an orthographic projection of the touch wiring on the isolation structure being a first projection, and the first projection being not distributed between at least one isolation opening and the first opening adjacent to the at least one isolation opening.

In a third aspect, the embodiments of the present application provide a display panel, including:
an array substrate;
an isolation structure disposed on a side of the array substrate, the isolation structure being provided with a plurality of isolation openings and a plurality of first openings;
a light emitting function layer including a plurality of light emitting units, at least a part of the light emitting unit being disposed within the isolation opening;
a touch layer disposed on a side of the isolation structure away from the array substrate, the touch layer including one or more touch wirings, the touch wirings enclosing and forming a plurality of meshes, and a mesh region corresponding to at least one of the meshes being provided with the isolation opening and the first opening.

In a fourth aspect, the embodiments of the present application provide a display panel, including:
an array substrate;
a light emitting function layer disposed on a side of the array substrate and including a plurality of light emitting units;
a touch layer disposed on a side of the light emitting function layer away from the array substrate, the touch layer including one or more touch wirings, the touch wirings enclosing and forming a plurality of meshes, a mesh region corresponding to at least one of the meshes including a light emitting region and a light transmission region, and the light emitting region being provided with the light emitting unit.

In a fifth aspect, the embodiments of the present application provide a display panel, including:
an array substrate;
an isolation structure disposed on a side of the array substrate, the isolation structure being provided with a plurality of isolation openings and a plurality of first openings;
a light emitting function layer including a plurality of light emitting units, at least a part of the light emitting unit being disposed within the isolation opening;
a touch layer disposed on a side of the isolation structure away from the array substrate, the touch layer including one or more touch wirings, an orthographic projection of the touch wiring on the array substrate being located within an orthographic projection of the isolation structure on the array substrate; wherein a light transmittance of the display panel is greater than or equal to 0.5%.

In a sixth aspect, the embodiments of the present application provide a display device, including the display panel of any embodiment of the first aspect or the second aspect described above.

In the display panel and the display device provided in the embodiments of the present application, by setting the first openings, the light transmittance of the display panel may be improved; by setting the orthographic projection of the touch wiring on the array substrate as being located within the orthographic projection of the isolation structure on the array substrate, the problem that the touch layer blocks the light entering the first openings or blocks the light exiting the isolation openings may be avoided or reduced, and the light transmittance of the display panel may be improved; by setting the first projection as surrounding a part of the boundary of at least one of the first openings, it is beneficial to increase the size of the first opening and improve the light transmittance.

### BRIEF DESCRIPTION OF THE DRAWINGS

In order to clearly illustrate the technical solutions of the embodiments of the present application, the accompanying drawings used in the embodiments of the present application are briefly described below. Obviously, the drawings described below are only some embodiments of the present application. For those of ordinary skill in the art, other relevant drawings can also be obtained without creative efforts according to these accompanying drawings.

FIG. 1 is a schematic partial structure diagram of a display panel provided by some embodiments of the present application;

FIG. 2 is a schematic cross-sectional diagram at A-A in FIG. 1 provided by an embodiment of the present application;

FIG. 3 is a schematic partial structure diagram of a display panel provided by an embodiment of the present application;

FIG. 4 is a schematic cross-sectional diagram at B-B in FIG. 3 provided by an embodiment of the present application;

FIG. 5 is a schematic partial plane structure diagram of a display panel provided by some embodiments of the present application;

FIG. 6 is a schematic partial plane structure diagram of a display panel provided by some embodiments of the present application;

FIG. 7 is a schematic partial plane structure diagram of a display panel provided by some embodiments of the present application;

FIG. 8 is a schematic partial plane structure diagram of a display panel provided by some embodiments of the present application;

FIG. 9 is a schematic partial plane structure diagram of a display panel provided by some embodiments of the present application;

FIG. 10 is a schematic partial plane structure diagram of a display panel provided by some embodiments of the present application;

FIG. 11 is a schematic partial plane structure diagram of a display panel provided by some embodiments of the present application;

FIG. 12 is a schematic partial plane structure diagram of a display panel provided by some embodiments of the present application;

FIG. 13 is a schematic plane structure diagram of a display panel provided by some embodiments of the present application;

FIG. 14 is a schematic partial plane structure diagram of a display panel provided by some embodiments of the present application;

FIG. 15 is a schematic partial plane structure diagram of a display panel provided by an embodiment of the present application;

FIG. 16 is a schematic partial enlarged diagram of a second display region of a display panel provided by an embodiment of the present application;

FIG. 17 is a schematic partial cross-sectional diagram of a display panel provided by an embodiment of the present application;

FIG. 18 is a schematic partial cross-sectional diagram of a display panel provided by an embodiment of the present application;

FIG. 19 is a schematic top view of an orthographic projection of an isolation structure on an array substrate forming a net structure provided by an embodiment of the present application;

FIG. 20 is a schematic partial cross-sectional diagram of a display panel provided by an embodiment of the present application;

FIG. 21 is a schematic top view of an orthographic projection of a touch wiring and a signal wiring on a substrate provided by an embodiment of the present application;

FIG. 22 is a schematic partial enlarged diagram of a first display region of a display panel provided by an embodiment of the present application;

FIG. 23 is a schematic cross-sectional diagram at C-C in FIG. 22 provided by an embodiment of the present application;

FIG. 24 is a schematic plane structure diagram of a display module provided by an embodiment of the present application;

FIG. 25 is a schematic partial structure diagram of a first display region of the display module shown in FIG. 24;

FIG. 26 is a schematic arrangement diagram of touch electrode components, light emitting units and first openings of the display module shown in FIG. 24;

FIG. 27 is another schematic arrangement diagram of touch electrode components, light emitting units and first openings of the display module shown in FIG. 24;

FIG. 28 is another schematic arrangement diagram of touch electrode components, light emitting units and first openings of the display module shown in FIG. 24;

FIG. 29 is another schematic arrangement diagram of touch electrode components, light emitting units and first openings of the display module shown in FIG. 24;

FIG. 30 is another schematic arrangement diagram of touch electrode components, light emitting units and first openings of the display module shown in FIG. 24;

FIG. 31 is another schematic arrangement diagram of touch electrode components, light emitting units and first openings of the display module shown in FIG. 24;

FIG. 32 is a schematic partial enlarged diagram of FIG. 31.

### DETAILED DESCRIPTION

Features and exemplary embodiments of various aspects of the present application will be described in detail below. In order to make the objects, technical solutions and advantages of the present application clearer, the present application is further described in detail below with reference to the accompanying drawings and specific embodiments. It should be understood that the specific embodiments described herein are only used to explain the present application, but not to limit the present application. For those skilled in the art, the present application can be implemented without some of these specific details. The following description of the embodiments is only to provide a better understanding of the present application by illustrating examples of the present application.

It should be understood that when describing the structure of a component, a layer or a region being “above” or “over” another layer or another region may mean that the layer or the region is directly above the another layer or another region, or other layers or regions are included between the layer or the region and the another layer or another region. Further, under a condition that the component is flipped, the layer or the region will be located “under” or “below” the another layer or another region.

In the related art, a light sensor is disposed on a side of the display panel. The light sensor can receive the light passing through the display panel. The light transmittance of the display panel is poor, which affects the recognition accuracy of the light sensor.

To solve the above problems, the embodiments of the present application provide a display panel and a display device. The embodiments of the display panel and the display device will be explained in combination with the drawings.

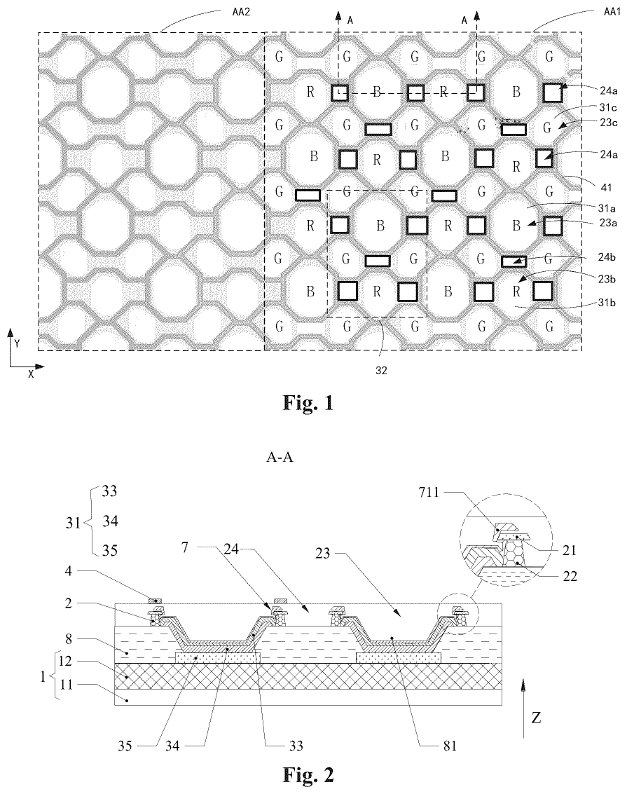

In a first aspect, the present application provides a display panel. As shown in FIGS. 1 and 2, the display panel includes an array substrate 1, an isolation structure 2, a light emitting function layer and a touch layer 4. The isolation structure 2 is disposed on a side of the array substrate 1, and the isolation structure 2 is provided with a plurality of isolation openings 23 and a plurality of first openings 24; the light emitting function layer includes a plurality of light emitting units 31, at least a part of the light emitting unit 31 is disposed within the isolation opening 23; the touch layer 4 is disposed on a side of the isolation structure 2 away from the array substrate 1, the touch layer 4 includes one or more touch wirings 41, an orthographic projection of the touch wiring 41 on the array substrate 1 is located within an orthographic projection of the isolation structure 2 on the array substrate 1, an orthographic projection of the touch wiring 41 on the isolation structure 2 is a first projection, and the first projection surrounds a part of a boundary of at least one of the first openings 24.

The display panel provided in the embodiments of the present application may be a display panel based on the Organic Light Emitting Diode (OLED) technology. Here, the isolation structure 2 is described in patent applications No. PCT/CN2023/134518, 202310759370.2, 202310740412.8, 202310707209.0, 202311346196.5, and 202310909421.5 for reference.

In the display panel provided by the embodiments of the present application, the array substrate 1 may not only provide support for the isolation structure 2, but also provide electrical signals for the light emitting function layer and the touch layer 4. There are various arrangements of the array substrate 1. In some embodiments, the array substrate 1 may include a substrate 11 and a driving circuit layer 12 disposed on the substrate 11. The substrate 11 may be a silicon substrate, or may be a flexible substrate 11, such as a polyimide. The driving circuit layer 12 may include a pixel driving circuit, a plurality of conductive connecting structures that are stacked, a plurality of driving units, and the like. Exemplarily, the pixel driving circuit provided in the driving circuit layer 12 includes a transistor and a storage capacitor. Exemplarily, each driving unit may include one or more semiconductor switching devices. The semiconductor switching device may be formed by a plurality of membrane layers in the array substrate 1, for example, the semiconductor switching device may be a thin film transistor formed by the plurality of membrane layers.

The isolation structure 2 encloses and forms a plurality of isolation openings 23, and a plurality of first openings 24 are provided on the isolation structure 2. The isolation opening 23 is used for limiting the light emitting unit 31, and at least a part of the light emitting unit 31 is located within the isolation opening 23. That is, an orthographic projection of the at least a part of the light emitting unit 31 on the array substrate 1 is located within an orthographic projection of the isolation opening 23 on the array substrate 1. The number of the isolation openings 23 may correspond to the number of light emitting units 31 in a one to one relationship, or a plurality of light emitting units 31 are provided within one isolation opening 23. The light entering the display panel from one side of the display panel may emit from the other side of the display panel through the first opening 24, and a light sensor located on the side of the display panel receives the light to achieve photoelectric conversion. The light sensor may specifically be an infrared sensor, a camera, and the like.

The plurality of light emitting units 31 may be light emitting units 31 capable of emitting light of different colors. For example, the light emitting unit 31 may be a red light emitting unit 31 capable of emitting a red light, a green light emitting unit 31 capable of emitting a green light, and a blue light emitting unit 31 capable of emitting a blue light. The number of isolation openings 23 and the number of the first opening 24 may be determined as required. For example, one red light emitting unit 31, two green light emitting units 31 and one blue light emitting unit 31 respectively located within four isolation openings 23 are combined to form a pixel light emitting group 32, and a plurality of pixel light emitting groups 32 are arranged in arrays along a first direction X and a second direction Y.

The orthographic projection of the first opening 24 on the array substrate 1 does not overlap with the orthographic projection of the light emitting unit 31 on the array substrate 1. The first opening 24 may be a transparent opening.

By setting the orthographic projection of the first opening 24 on the array substrate 1 as not overlapping with the orthographic projection of the light emitting unit 31 on the array substrate 1, the external light may not be blocked by the light emitting unit 31, thereby allowing the external light to pass smoothly through the first opening 24.

The touch layer 4 enables the display device to perform touch operation, and the touch layer 4 can be arranged on the light emitting side of the light emitting function layer. In order to avoid the touch layer 4 from affecting the display of the light emitting function layer, the touch layer 4 can be prepared with a light transmission material. The touch layer 4 may be a mesh electrode film based on the metal mesh capacitive touch technology (Metal Mesh). The touch layer 4 may include one or more touch wirings 41, the touch wiring 41 may be a patterned mesh line, the touch wiring 41 may include one or more conductive mesh lines, and touch wiring 41 may be prepared by the exposure etching technology. A plurality of touch wirings 41 may be connected. The touch wiring 41 may be provided with a break for disconnecting the mesh lines, and the mesh lines on two sides of the break may be respectively used as a driving electrode and an induction electrode that are mutually compatible, so as to collect touch signals. The adjacent touch wirings 41 may also be disconnected by a break, so that the adjacent touch wirings 41 may be respectively used as a driving electrode and an induction electrode that are mutually compatible, so as to collect touch signals. The plurality of touch wirings 41 are arranged in the display panel, so that the display panel can have touch function.

The “orthographic projection” described in the present application may be a projection along a third direction Z, which may be a thickness direction of the display panel, or a direction from the array substrate 1 to the light emitting function layer. Optionally, please refer again to FIGS. 1-2, the orthographic projection of the touch wiring 41 on the array substrate 1 does not overlap with the orthographic projection of the isolation opening 23 or the first opening 24 on the array substrate 1.

Under a condition that the orthographic projection of the touch wiring 41 on the array substrate 1 overlaps with the orthographic projection of the isolation opening 23 on the array substrate 1, the overlapping part of the touch wiring 41 will block the light emitted by the light emitting unit 31, thereby affecting the transmittance of the light emitted by the light emitting unit 31.

Under a condition that the orthographic projection of the touch wiring 41 on the array substrate 1 overlaps with the orthographic projection of the first opening 24 on the array substrate 1, the overlapping part of the touch wiring 41 will block the external light from reaching the position of the device in the first display region AA1, thereby affecting the accuracy of the device. Furthermore, there is no isolation structure 2 or the second electrode 35 of the light emitting unit 3 performing shielding between the touch wiring 41 and the signal wiring 121 of the array substrate 1, and thus the touch wiring 41 and the signal wiring 121 of the array substrate 1 will interfere with each other, thereby reducing the display quality and touch accuracy of the display panel.

In this embodiment, setting the orthographic projection of the touch wiring 41 on the array substrate 1 as not overlapping with the orthographic projection of the isolation opening 23 and/or the first opening 24 on the array substrate 1 may not only increase the transmittance of the light emitted by the light emitting unit 31, but also increase the light transmittance of the first display region AA1.

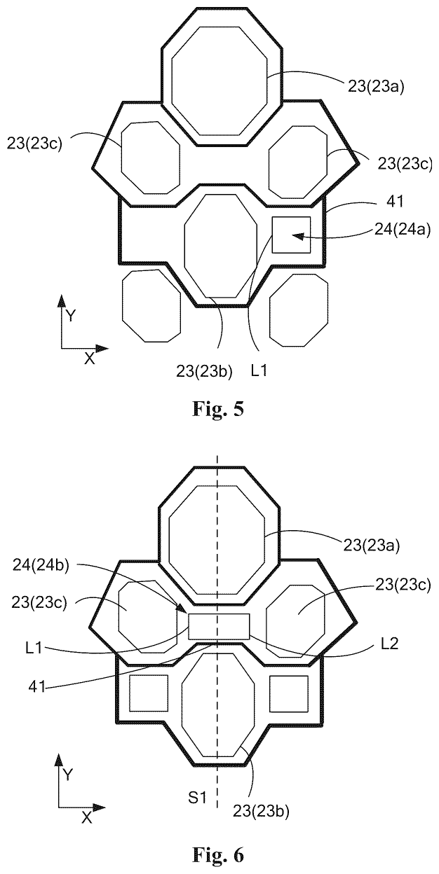

The first projection surrounds a part of a boundary of at least one of the first openings 24, so that the first projection is along the first opening 24, and the first projection does not surround another part of the boundary of the at least one of the first openings 24, which increases the size of the first opening 24, and improves the light transmittance of the display panel. For example, in the embodiment shown in FIG. 5, the touch wiring 41 does not surround the left boundary of the first opening 24, and the first projection of the touch wiring 41 surrounds the upper, lower and right boundary of the first opening 24, so that the left boundary of the first opening 24 can be shifted or expanded to the left, thereby increasing the size of the first opening 24.

The display panel provided in the present application may also include a cover plate covering a side of the touch layer 4 away from the array substrate 1, an optical adhesive layer located between the cover plate and the touch layer 4, an encapsulation layer for encapsulating the light emitting unit 31, and the like.

In the embodiments provided in the present application, by setting the first openings 24, the light transmittance of the display panel may be improved; by setting the orthographic projection of the touch wiring 41 on the array substrate 1 as being located within the orthographic projection of the isolation structure 2 on the array substrate 1, the problem that the touch layer 4 blocks the light entering the first openings 24 or blocks the light exiting the isolation openings 23 may be avoided or reduced, and the light transmittance of the display panel may be improved; by setting the first projection as surrounding a part of the boundary of at least one of the first openings 24, it is beneficial to increase the size of the first opening 24 and improve the light transmittance.

In some embodiments, the first projection of the touch wiring 41 does not surround another part of the at least one of the first openings 24, the first opening 24 is located between adjacent isolation openings 23, and the first projection is not distributed between a part of a boundary of the first opening 24 and the isolation opening 23.

The first opening 24 is located between adjacent isolation openings 23, and the adjacent isolation openings 23 and the first opening 24 are separated by the isolation structure 2. The first opening 24 is provided between the adjacent isolation openings 23, so that this region can emit light through the light emitting unit 31 in the isolation opening 23, and the light on a side of the display panel can pass through the first opening 24. The first projection is not distributed between a part of the boundary of the first opening 24 and the isolation opening 23, so that the space reserved for setting the touch wiring 41 between the first opening 24 and the isolation opening 41 can be omitted, which can provide a smaller distance between the first opening 24 and the isolation opening 23, and can increase the sizes of the first opening 24 and the isolation opening 23, thereby increasing the light transmittance of the display panel.

In some embodiments, please refer again to FIGS. 1-2, the orthographic projection of the touch wiring 41 on the array substrate 1 is located between the orthographic projections of the adjacent light emitting units 31 on the array substrate 1. By setting the touch wiring 41 as being located between the adjacent light emitting units 31, the light emitting unit 31 may have a large light emitting perspective, so that the touch wiring 41 has little influence on the overall light transmittance and color bias of the display panel.

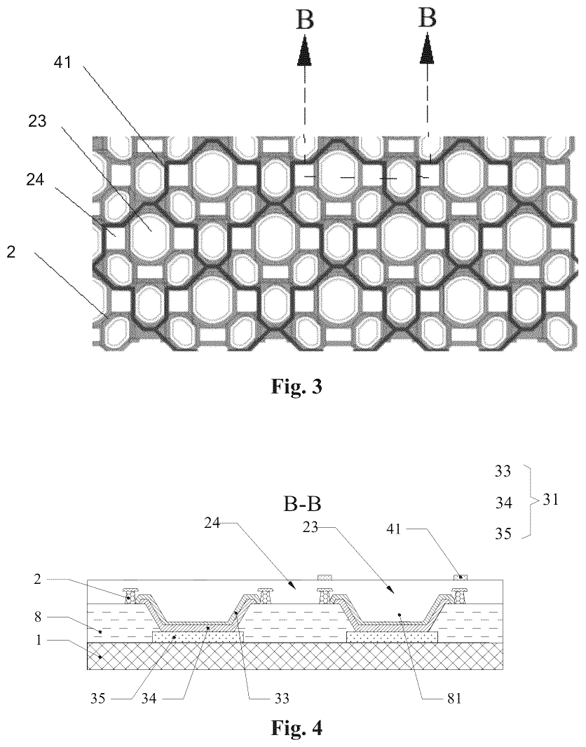

In some embodiments, please refer to FIGS. 3 and 4, a shape of an orthographic projection of the first opening 24 on the array substrate 1 includes a square or circle. For example, the shape of the orthographic projection of the first opening 24 on the array substrate 1 includes a square, and the shape of the orthographic projection of the first opening 24 on the array substrate 1 may also be set as other shapes, which is not limited to the square or circle proposed in this embodiment.

Optionally, please refer again to FIG. 3, the shape of the orthographic projection of the first opening 24 on the array substrate 1 is rectangular; and under a condition that the shape of the orthographic projection of the first opening 24 on the array substrate 1 is rectangular, the touch wiring 41 extends along a long side direction of the first opening 24. By setting the touch wiring 41 as extending along the long side direction of the first opening 24, the distance between the touch wiring 41 and the first opening 24 may be increased, thereby further reducing the degree of interaction between the touch wiring 41 and the signal wiring 121 in the array substrate 1.

Please refer to FIGS. 1 to 6, in some embodiments, the shape of the orthographic projection of the first opening 24 on the array substrate 1 is a polygon, and the first opening 24 includes a plurality of boundary lines; the first opening 24 and the touch wiring 41 satisfy at least one of:
(1) the first projection being not distributed between a boundary line of the first opening 24 and the isolation opening 23;
(2) the first projection being not distributed between either one of two opposite boundary lines of the first opening 24 and a corresponding isolation opening 23 adjacent to the either one of the two opposite boundary lines of the first opening 24;
(3) the first projection being not distributed between a plurality of contiguous boundary lines of the first opening 24 and the isolation opening 23;
(4) at least one of the first openings 24 having symmetry relative to a first symmetry axis, and a boundary of the at least one of the first openings 24 not surrounded by the first projection having symmetry relative to the first symmetry axis.

The shape of the orthographic projection of the first opening 24 on the array substrate 1 is a polygon, so that the first opening 24 has a plurality of boundary lines that are connected end to end. In the following description, the shape of the orthographic projection of the first opening 24 on the array substrate 1 is illustrated as a quadrilateral.

Exemplarily, as shown in FIG. 5, the first projection is not distributed between a boundary line L1 of the first opening 24 and the isolation opening 23, and the first projection is arranged around other boundary lines of the first opening 24 other than the boundary line L1. When forming the first opening 24, by setting the first projection as being not distributed between a boundary line of the first opening 24 and the isolation opening 23, both the isolation opening 23 and the first opening 24 may have a larger distribution space in the region between the boundary line L1 and the isolation opening 23, thereby increasing the density and size of the isolation opening 23 and the first opening 24.

Exemplarily, as shown in FIG. 6, the first projection is not distributed between either one of two opposite boundary lines of the first opening 24 and a corresponding isolation opening 23 adjacent to the either one of the two opposite boundary lines of the first opening 24, and the first projection is arranged around other boundary lines of the first opening 24 other than the boundary lines L1 and L2. When forming the first opening 24, by setting the touch wiring 41 as being not distributed between either one of two opposite boundary lines (L1 and L2) of the first opening 24 and a corresponding isolation opening 23 adjacent to the either one of the two opposite boundary lines (L1 and L2) of the first opening 24, one of the isolation openings 23 and the first opening 24 may have a larger distribution space in the region between the boundary line L1 and the one of the isolation openings 23, and the other of the isolation opening 23 and the first opening 24 may have a larger distribution space in the region between the boundary line L2 and the other of the isolation openings 23, thereby increasing the density and size of the isolation openings 23 and the first opening 24.

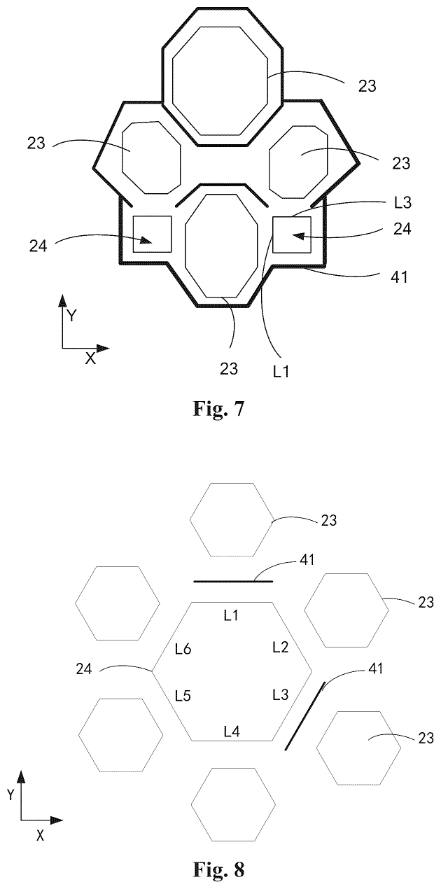

Exemplarily, as shown in FIG. 7, the touch wiring 41 is not distributed between a plurality of contiguous boundary lines of the first opening 24 and the isolation opening 23, and the first projection is arranged around other boundary lines of the first opening 24 other than the boundary lines L1 and L3. When forming the first opening 24, by setting the touch wiring 41 as being not distributed between a plurality of contiguous boundary lines (L1 and L3) of the first opening 24 and the isolation opening 23, one of the isolation openings 23 and the first opening 24 may have a larger distribution space in the region between the boundary line L1 and the one of the isolation openings 23, and the other of the isolation opening 23 and the first opening 24 may have a larger distribution space in the region between the boundary line L3 and the other of the isolation openings 23, thereby increasing the density and size of the isolation openings 23 and the first opening 24.

Exemplarily, as shown in FIG. 6, the first opening 24 has symmetry relative to the first symmetry axis S1, and the boundary lines L1 and L2 of the first opening 24 not surrounded by the first projection has symmetry relative to the first symmetry axis S1. When forming the first opening 24, by setting the touch wiring 41 as being not distributed between either one of the boundary lines L1 and L2 of the first opening 24 having symmetry relative to the first symmetry axis S1 and a corresponding isolation opening 23 adjacent to the either one of the boundary lines L1 and L2 of the first opening 24, one of the isolation openings 23 and the first opening 24 may have a larger distribution space in the region between the boundary line L1 and the one of the isolation openings 23, and the other of the isolation opening 23 and the first opening 24 may have a larger distribution space in the region between the boundary line L2 and the other of the isolation openings 23, thereby increasing the density and size of the isolation openings 23 and the first opening 24.

It is understood by those skilled in the art that the shape of the orthographic projection of the first opening 24 on the array substrate 1 may also be a pentagon, a hexagon, a heptagon, and so on. For the same first opening 24, the following situations may occur simultaneously: the touch wiring 41 is not distributed between a boundary line of the first opening 24 and the isolation opening 23, the touch wiring 41 is not distributed between either one of two opposite boundary lines of the first opening 24 and the isolation opening 23, and the touch wiring 41 is not distributed between a plurality of contiguous boundary lines of the first opening 24 and the isolation opening 23. For example, as shown in FIG. 8, the shape of the orthographic projection of the first opening 24 on the array substrate 1 is a hexagon. In the boundary lines L1 to L6, the first projection of the touch wiring 41 is not distributed between the boundary line L2 and the isolation opening 23 adjacent to the boundary line L2; the first projection of the touch wiring 41 is not distributed between either one of the opposite boundary lines L2 and L5 and the isolation opening 23 adjacent to the either one of the opposite boundary lines L2 and L5; and the first projection of the touch wiring 41 is not distributed between the connected boundary lines L4, L5 and L6 and the isolation openings 23 adjacent to the connected boundary lines L4, L5 and L6.

Referring to FIGS. 1 and 5, in some embodiments, the plurality of light emitting units 31 include a first light emitting unit 31a for emitting a first color light and a second light emitting unit 31b for emitting a second color light, the plurality of isolation openings 23 include a first isolation opening 23a and a second isolation opening 23b, at least a part of the first light emitting unit 31a is located within the first isolation opening 23a, and at least a part of the second light emitting unit 31b is located within the second isolation opening 23b;

the plurality of first openings 24 include a plurality of first sub-openings 24a, the first sub-opening 24a is disposed between the first isolation opening 23a and the second isolation opening 23b adjacent to the first isolation opening 23a in a first direction X.

The first color light may be a blue light, the second color light may be a red light, the first light emitting unit 31a is used to emit the blue light, and the second light emitting unit 31b is used to emit the red light. A plurality of first light emitting units 31a and a plurality of second light emitting units 31b may be arranged alternately along the first direction X, and a plurality of first sub-openings 24a may be spaced apart along the first direction X and may be disposed between the first light emitting unit 31a and the second light emitting unit 31b adjacent to the first light emitting unit 31a. Therefore, the external light may inject from one side of the display panel through the first sub-opening 24a between the first light emitting unit 31a and the second light emitting unit 31b.

In some embodiments, a part of the first projection is distributed along a plurality of continuously connected boundary lines of the first sub-opening 24a, which increases the distribution density of the touch wiring 41 in the region where the first sub-opening 24a is located, and improves the touch sensitivity.

Optionally, the first projection is distributed between the first sub-opening 24a and the first light emitting unit 31a, the first projection is not distributed between the first sub-opening 24a and the second light emitting unit 31b, and a projection area of the first isolation opening 23a on the array substrate 1 is greater than a projection area of the second isolation opening 23b on the array substrate 1.

Since the projection area of the first isolation opening 23a on the array substrate 1 is greater than the projection area of the second isolation opening 23b on the array substrate 1, a projection area of the first light emitting unit 31a located in the first isolation opening 23a on the array substrate 1 may be larger than a projection area of the second light emitting unit 31b located in the second isolation opening 23b on the array substrate 1. The first projection is distributed between the first sub-opening 24a and the first light emitting unit 31a, and the first projection is not distributed between the first sub-opening 24a and the second light emitting 31b has a larger light emitting angle, which is advantageous to increase the light emitting rate of the second light emitting unit 31b.

Referring to FIG. 5, in some embodiments, the plurality of light emitting units 31 further include a third light emitting unit 31c for emitting a third color light, the plurality of isolation openings 23 further comprise a third isolation opening 23c, at least a part of the third light emitting unit 31c is located in the third isolation opening 23c; the plurality of first openings 24 further include a plurality of second sub-openings 24b, the second sub-opening 24b is disposed between adjacent third isolation openings 23c.

The third color light may be a green light, and the third light emitting unit 31c is used to emit the green light. The third isolation openings 23c may be spaced apart along the second direction Y, and the second sub-opening 24b may be disposed between the adjacent third isolation openings 23c along the first direction X. By providing the second sub-opening 24b between the third isolation openings 23c, the light transmittance between the third light emitting units 31c may be increased.

In some embodiments, the plurality of the first sub-openings 24a are arranged in rows along the first direction X and form a plurality of rows of the first sub-openings 24a; the plurality of the second sub-openings 24b are arranged in rows along the first direction X and form a plurality of rows of the second sub-openings 24b, the second sub-opening 24b and the first sub-opening 24a are in different rows.

The plurality of rows of first sub-openings 24a may be spaced apart along the second direction Y. The plurality of rows of second sub-openings 24b may be spaced apart along the second direction Y. The first sub-opening 24a and the second sub-opening 24b are located in different rows. For example, the blue light emitting units 31a and the red light emitting units 31b are alternately arranged as a first pixel line, the plurality of green light emitting units 31c are arranged as a second pixel line, and a plurality of first pixel lines and a plurality of second pixel lines are alternately arranged along the second direction Y. The first sub-opening 24a is disposed between the blue light emitting unit 31a and the red light emitting unit 31b spaced along the first direction X, and the second sub-opening 24b is disposed between the green light emitting units 31c spaced along the first direction X.

The second sub-opening 24b and the first sub-opening 24a are located in different rows, thereby simplifying the arrangement design of the first opening 24, and simplifying the arrangement design of the touch wiring 41 corresponding to the first opening 24. Optionally, the second sub-openings 24b arranged in rows and the first sub-openings 24a arranged in rows are spaced apart along the second direction Y.

In some embodiments, a part of the first projection is distributed along two opposite boundary lines of the second sub-opening 24b.

The first isolation opening 23a and the second isolation opening 23b are arranged along the second direction Y, and the second sub-opening 24b is located between the first isolation opening 23a and the second isolation opening 23b that are arranged along the second direction Y. The first projection is distributed between the second sub-opening 24b and the first isolation opening 23a and between the second sub-opening 24b and the second isolation opening 23b, and the first projection is not distributed between the second sub-opening 24b and the third light emitting unit 31c adjacent to the second sub-opening 24b, which is beneficial to increase the size of the second sub-opening 24b, thereby increasing the transmittance.

Optionally, the projection area of the third isolation opening 23c on the array substrate 1 is less than the projection area of the first isolation opening 23a on the array substrate 1, and less than the projection area of the second isolation opening 23b on the array substrate 1, so that the projection area of the third light emitting unit 31c located in the third isolation opening 23c on the array substrate 1 is less than the projection area of the first light emitting unit 31a located in the first isolation opening 23a on the array substrate 1, and less than the projection area of the second light emitting unit 31b located in the second isolation opening 23b on the array substrate 1. Further, the first projection is distributed between the second sub-opening 24b and the first isolation opening 23a, and between the second sub-opening 24b and the second isolation opening 23b, and the first projection is not distributed between the second sub-opening 24b and the third light emitting unit 31c adjacent to the second sub-opening 24b. Therefore, compared to the first light emitting unit 31a and the second light emitting unit 31b, the third light emitting unit 31c has a larger light emitting angle, which is advantageous to increase the light emitting rate of the third light emitting unit 31c.

In some embodiments, the first projection surrounds an entire boundary of the first isolation opening 23a, at least a part of the first projection surrounds a part of a boundary of the second isolation opening 23b, and two opposite boundary lines of the second isolation opening 23b are not surrounded by the first projection.

The boundary line of the second isolation opening 23b facing the first isolation opening 23a along a first direction X is not surrounded by the first projection of the touch wiring 41, which is beneficial to increase the length of the first opening 24 located between the second isolation opening 23b and the first isolation opening 23a along the first direction X, thereby increasing the size of the first opening 24 and increasing the transmittance.

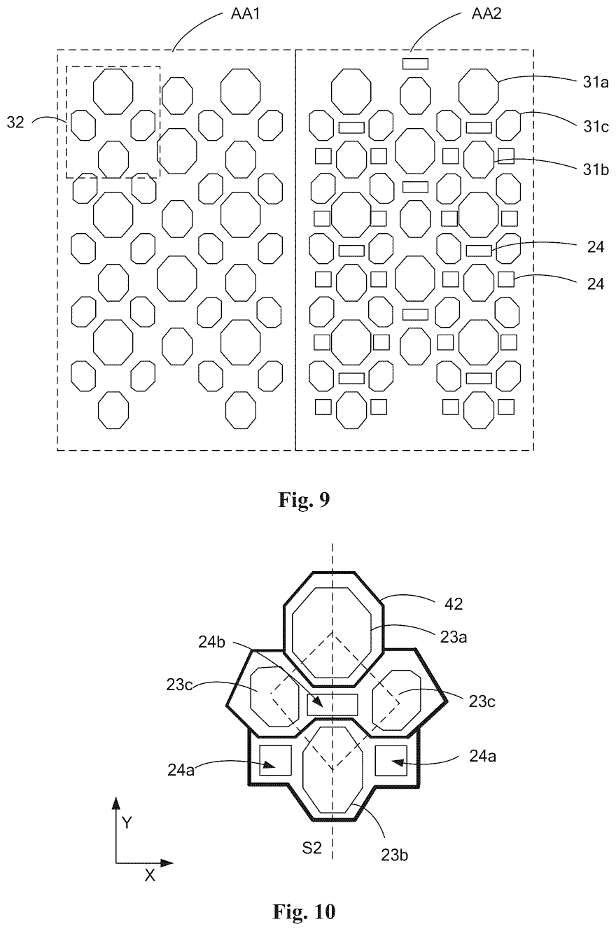

Referring to FIGS. 9 and 10, in some embodiments, the touch wirings 41 enclose and form a plurality of meshes 42, the plurality of meshes 42 correspond to a plurality of mesh regions in a one to one relationship, at least one of the mesh regions 42 is provided with the isolation opening 23 and the first opening 24 adjacent to the isolation opening 23.

The orthographic projection of the mesh 42 on the array substrate 1 can completely overlap with the mesh region. One mesh region 42 may be provided with one pixel light emitting group 32. For example, one first light emitting unit 31a, one second light emitting unit 31b, and two third light emitting units 31c form one pixel light emitting group 32, and the pixel light emitting group 32 is disposed in the mesh enclosed and formed by the touch wiring 41. The mesh 42 can be repeatedly laid, thereby simplifying the design of the touch wiring 41.

In some embodiments, the touch wirings 41 enclosing and forming two adjacent meshes 42 have a common touch wiring 41.

For example, for the common touch wiring 41 shared between two adjacent meshes A and B, the common touch wirings 41 encloses and forms the mesh A with other touch wirings 41 on the one hand, and encloses and forms the mesh B with other touch wirings 41 on the other hand.

The touch wirings 41 enclosing and forming two adjacent meshes 42 have a common touch wiring 41, thereby increasing the proportion of the touch wirings 41 distributed between the adjacent isolation openings 23, and reducing the space occupied by the touch wirings 41 between the adjacent isolation openings 23, which helps to increase the size or distribution density of the isolation openings 23.

In some embodiments, at least one of the meshes 42 has symmetry.

By setting the mesh region 42 as having symmetry, the uniformity of the distribution of the touch wirings 41 may be improved.

In some embodiments, the plurality of isolation openings 23 include a first isolation opening 23a, the plurality of the light emitting units 31 include a first light emitting unit 31a for emitting a first color light, at least a part of the first light emitting unit 31a is located within the first isolation opening 23a; an orthographic projection of the touch wirings 41 enclosing and forming at least one of the meshes 42 on the isolation structure 2 surrounds an entire boundary of the first isolation opening 23a.

The orthographic projection of the touch wiring 41 on the isolation structure 2 surrounds the entire boundary of the first isolation opening 23a, thereby improving the touch sensitivity of the region where the first light emitting unit 31a is distributed. Optionally, in the light emitting units 31 for emitting light of different colors, the projection area of the first light emitting unit 31a on the array substrate 1 is the largest, thereby reducing the maximum interval distance between the adjacent touch wirings 41, and increasing the distribution density of the touch wirings 41.

In some embodiments, the plurality of isolation openings 23 include a second isolation opening 23b, the plurality of light emitting units 31 comprise a second light emitting unit 31b for emitting a second color light, at least a part of the second light emitting unit 31b is located within the second isolation opening 23b, and at least one of the mesh regions 42 is provided with the second isolation opening 23b and the first openings 24 on two opposite sides of the second isolation opening 23b;

in a same mesh region 42, the first projection is not distributed between the second isolation opening 23b and the first opening 24 adjacent to the second isolation opening 23b.

In the same mesh region 42, the second isolation opening 23b is adjacent to at least one of the first openings 24, and the first projection is not distributed between the second isolation opening 23b and the first opening 24 adjacent to the second isolation opening 23b, thereby increasing the length of the second isolation opening 23b along the direction that the touch wiring 41 is not distributed. Optionally, the first openings 24 may be located on two opposite sides of the second isolation opening 23b along the first direction X, and the touch wiring 41 is not distributed between the second isolation opening 23b and the first openings 24, thereby increasing the length of the second isolation opening 23b along the first direction X.

In some embodiments, the second isolation opening 23b has symmetry relative to a second symmetry axis S2, and a boundary of the second isolation opening 23b not surrounded by the first projection has symmetry relative to the second symmetry axis S2.

The boundary of the second isolation opening 23b not surrounded by the first projection has symmetry relative to the second symmetry axis S2, thereby increasing the length of the second isolation opening 23b along the direction perpendicular to the second symmetry axis S2.

In some embodiments, the plurality of the isolation openings 23 include a third isolation opening 23c, the plurality of light emitting units 31 include a third light emitting unit 31c for emitting a third color light, at least a part of the third light emitting unit 31c is located in the third isolation opening 23c; and at least one of the mesh regions 42 is provided with the first opening 24 and third isolation openings 23c on two opposite sides of the first opening 24.

The third isolation openings 23c are disposed on two opposite sides of the first opening 24, so as to increase the light transmittance in the mesh region 42, and increase the light transmission uniformity in the mesh region.

In some embodiments, in a same mesh region 42, the first projection is not distributed between the third isolation opening 23c and the first opening 24 adjacent to the third isolation opening 23c.

In the same mesh region 42, the third isolation opening 23c and the first opening 24 adjacent to the third isolation opening 23c may be spaced apart along the first direction X, and the first projection is not distributed between the third isolation opening 23c and the first opening 24, thereby increasing the length of the first opening 24 along the first direction X.

In the same mesh region 42, one first light emitting unit 31a, one second light emitting unit 31b and two third light emitting units 31c are provided; and in the same mesh region 42, center points of the first light emitting unit 31a, the second light emitting unit 31b and the third light emitting units 31c are connected to form a virtual quadrilateral. For example, the virtual quadrilateral is shown by dotted lines in FIG. 10.

The first light emitting unit 31a and the second light emitting unit 31b arranged in the same mesh region 42 may be arranged along the second direction Y, and the two third light emitting units 31c may be arranged along the first direction X, and the first direction X intersects the second direction Y. The first sub-openings 24a are disposed on two sides of the second light emitting unit 31b along the first direction X, and the second sub-opening 24b is disposed between the two third light emitting units 31c. Thus, on the one hand, it is beneficial to ensure that the region provided with the first opening 24 has better light transmission performance, and on the other hand, the light emitting units 31 are arranged closer, thereby improving the pixel density and display effect of the display panel.

In some embodiments, the plurality of mesh regions 42 are arranged in rows along the first direction X and arranged in columns along the second direction Y intersecting the first direction X; in a same mesh region 42, the first light emitting unit 31a and the second light emitting unit 31b are spaced apart along the second direction Y, and the two third light emitting units 31c are spaced apart along the first direction X; in a same mesh region 42, two first openings 24 are disposed on two opposite sides of the first light emitting unit 31a along the first direction, and/or two first openings 24 are disposed on two opposite sides of the second light emitting unit 31b along the first direction X, and/or at least one first opening 24 is disposed between the two third light emitting units 31c.

Those skilled in the art may perform arrangement and combination according to the position relationship of the first openings 24 and the light emitting units 31 in the above mesh region 42, so as to obtain different arrangements for the first openings 24 and the light emitting units 31 in the mesh region 42.

Exemplarily, in the same mesh region 42, two first openings 24 are provided on two opposite sides of the first light emitting unit 31a along the first direction X, and at least one first opening 24 is provided between the two third light emitting units 31c.

A plurality of light emitting units 31 form pixel light emitting groups 32, and the pixel light emitting groups 32 are arranged in an array. One pixel light emitting group 32 includes one red light emitting unit 31b for emitting a red light, two green light emitting units 31c for emitting a green light, and one blue light emitting unit 31a for emitting a blue light. The first sub-openings 24a are provided on two sides of the red light emitting unit 31b, and along the second direction Y, the green light emitting unit 31c is provided between the first sub-opening 24a located in the same mesh region 42 as the green light emitting unit 31c and the first sub-opening 24a located in the other mesh region 42. The red light emitting unit 31b and the blue light emitting unit 31a are spaced apart along the second direction Y, and the second sub-opening 24b may be disposed between the red light emitting unit 31b and the blue light emitting unit 31a along the second direction Y. The two green light emitting units 31c are spaced apart along the first direction X, and the second sub-opening 24b may be disposed between the two green light emitting units 31c along the first direction X.

Exemplarily, in the same mesh region 42, two first openings 24 are provided on two opposite sides of the second light emitting unit 31b along the first direction X, and at least one first opening 24 is provided between the two third light emitting units 31c.

A plurality of light emitting units 31 form pixel light emitting groups 32, and the pixel light emitting groups 32 are arranged in an array. One pixel light emitting group 32 includes one red light emitting unit 31b for emitting a red light, two green light emitting units 31c for emitting a green light, and one blue light emitting unit 31a for emitting a blue light. The first sub-openings 24a are provided on two sides of the blue light emitting unit 31a, and along the second direction Y, the green light emitting unit 31c is provided between the first sub-opening 24a located in the same mesh region 42 as the green light emitting unit 31c and the first sub-opening 24a located in the other mesh region 42. The red light emitting unit 31b and the blue light emitting unit 31a are spaced apart along the second direction Y, and the second sub-opening 24b may be disposed between the red light emitting unit 31b and the blue light emitting unit 31a along the second direction Y. The two green light emitting units 31c are spaced apart along the first direction X, and the second sub-opening 24b may be disposed between the two green light emitting units 31c along the first direction X.

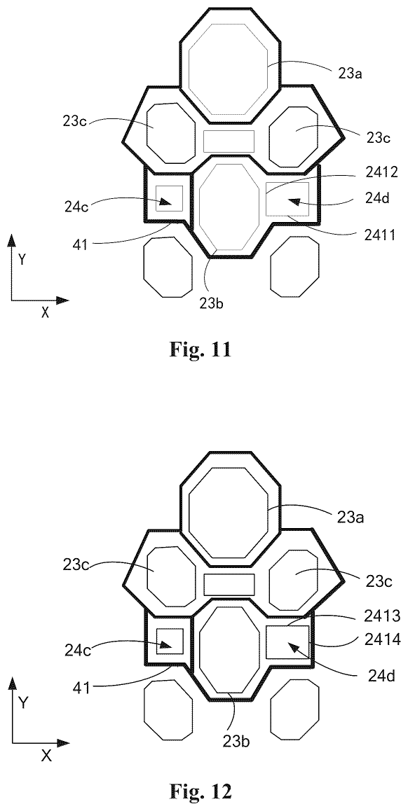

Referring to FIG. 11, in some embodiments, the plurality of first openings 24 comprise a third sub-opening 24c and a fourth sub-opening 24d, the first projection surrounds a part of a boundary of the third sub-opening 24c, a part of the first projection does not surround another part of the boundary of the third sub-opening 24c, a part of the first projection surrounds an entire boundary of the fourth sub-opening 24d, a projection area of the third sub-opening 24c on the array substrate 1 is greater than a projection area of the fourth sub-opening 24d on the array substrate 1.

When designing the first opening 24, a certain space should be reserved, so that under a condition that deviation occurs in the prepared touch wiring 41, the touch wiring 41 will not block the isolation opening 23 or the first opening 24. A part of the touch wiring 41 surrounds the entire boundary of the fourth sub-opening 24d, so that the entire boundary of the fourth sub-opening 24d require reserved space to set the touch wiring 41. The touch wiring 41 does not surround a part of the boundary of the third sub-opening 24c, so that the part of the boundary does not need to reserve space for setting the touch wiring 41. Therefore, it can be designed and prepared that the projection area of the third sub-opening 24c on the array substrate 1 is greater than the projection area of the fourth sub-opening 24d on the array substrate 1, and the light transmittance of the display panel may be increased by the larger size of the third sub-opening 24c.

In some embodiments, the third sub-opening 24c and the fourth sub-opening 24d both include a boundary line extending along the first direction X and a boundary line extending along the second direction Y, the first projection does not surround the boundary line of the third sub-opening 24c extending along the second direction Y, a length of the third sub-opening 24c along the first direction X is greater than a length of the fourth sub-opening 24d along the first direction X.

Since the touch wiring 41 does not surround the boundary line of the third sub-opening 24c extending along the second direction Y, the third sub-opening 24c may extend along the first direction X to obtain a larger size, so that the length of the third sub-opening 24c along the first direction X is greater than the length of the fourth sub-opening 24d along the first direction X.

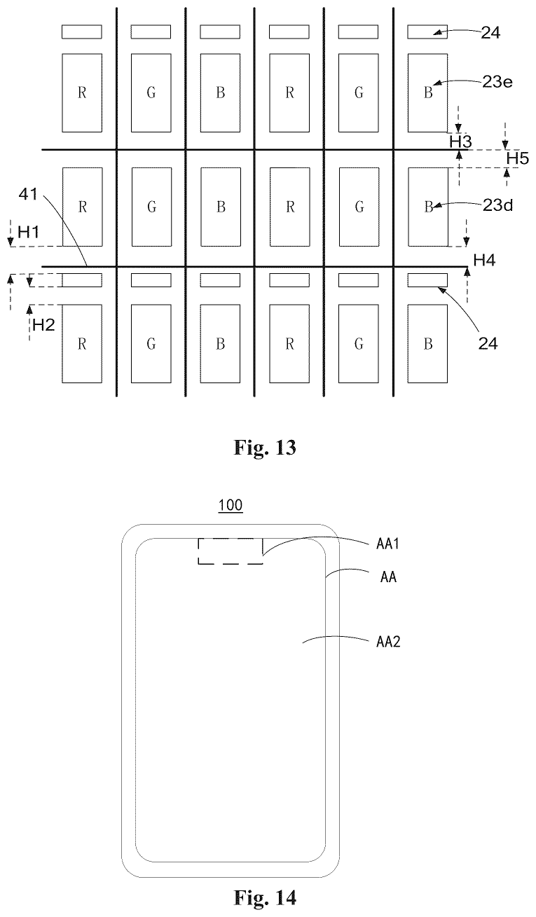

Referring to FIGS. 11 and 13, in some embodiments, the first opening 24 includes the first boundary line 2411 and the second boundary line 2412, and at least a part of the touch wiring 41 is located between the first boundary line 2411 and the isolation opening 23, and the touch wiring 41 is not located between the second boundary line 2412 and the isolation opening 23; a minimum distance H1 of the first boundary line 2411 to a boundary of the isolation opening 23 adjacent to the first boundary line 2411 is greater than a minimum distance H2 of the second boundary line 2412 to a boundary of the isolation opening 23 adjacent to the second boundary line 2412.

Since space needs to be reserved between the first boundary line 2411 and the isolation opening 23 for setting the touch wiring 41, the minimum distance H1 of the first boundary line 2411 to the boundary of the isolation opening 23 adjacent to the first boundary line 2411 is greater than the minimum distance H2 of the second boundary line 2412 to the boundary of the isolation opening 23 adjacent to the second boundary line 2412, thereby increasing the minimum distance between the isolation opening 23 and the first opening 24.

In some embodiments, the minimum distance H1 of the first boundary line 2411 to the boundary of the isolation opening 23 adjacent to the first boundary line 2411 is greater than or equal to 11 um, and the minimum distance H2 of the second boundary line 2412 to the boundary of the isolation opening 23 adjacent to the second boundary line 2412 is greater than or equal to 5.5 um, thereby reducing or avoiding the touch wiring 41 from blocking the isolation opening 23 or the first opening 24 due to preparation errors.

For example, the minimum distance H1 of the first boundary line 2411 to the boundary of the isolation opening 23 adjacent to the first boundary line 2411 is equal to 11 um, and the minimum distance H2 of the second boundary line 2412 to the boundary of the isolation opening 23 adjacent to the second boundary line 2412 is equal to 5.5 um. For example, the minimum distance H1 of the first boundary line 2411 to the boundary of the isolation opening 23 adjacent to the first boundary line 2411 is equal to 15 um, and the minimum distance H2 of the second boundary line 2412 to the boundary of the isolation opening 23 adjacent to the second boundary line 2412 is equal to 7 um.

In some embodiments, the minimum distance of the boundary of the isolation opening 23 to the first projection is greater than or equal to 5 um, thereby avoiding the touch wiring 41 from blocking the light emitted by the light emitting unit 31 in the isolation opening 23 due to preparation errors. Optionally, the minimum distance of the boundary of the isolation opening 23 to the first projection is 5 um, 6 um, 10 um, 15 um, and the like.

Referring to FIG. 13, in some embodiments, the isolation openings 23 include a fourth isolation opening 23d and a fifth isolation opening 23e, a light emitting color of the light emitting unit in the fourth isolation opening 23d is the same as or different from a light emitting color of the light emitting unit in the fifth isolation opening 23e, and a minimum distance H3 from a boundary of the fourth isolation opening 23d to the touch wiring 41 is the same as a minimum distance H4 from a boundary of the fifth isolation opening 23e to the touch wiring 41. The minimum distance H4 from the fourth isolation opening 23d to one adjacent touch wiring 41 is the same as the minimum distance H4 from the fourth isolation opening 23d to the other adjacent touch wiring 41.

The light emitting unit placed in the fourth isolation opening 23d may be used for emitting any of the red light, the blue light and the green light, the light emitting unit placed in the fifth isolation opening 23e may be used for emitting any of the red light, the blue light and the green light, and the size and shape of the fourth isolation opening 23d and the fifth isolation opening 23e may be the same or different. For example, the fourth isolation opening 23d and the fifth isolation opening 23e are the isolation openings in the first isolation opening 23a, the second isolation opening 23b and the third isolation opening 23c that are used to place the light emitting units of the same color. The fourth isolation opening 23d and the fifth isolation opening 23e may be any two isolation openings in the first isolation opening 23a, the second isolation opening 23b, and the third isolation opening 23c. By setting the minimum distance H3 of the boundary of the fourth isolation opening 23d to the touch wiring as being the same as the minimum distance H4 of the boundary of the fifth isolation opening 23e to the touch wiring, it is advantages to avoid or reduce the touch wiring from blocking the light emitted by the light emitting units in the fourth isolation opening 23 d and the fifth isolation opening 23e due to preparation errors. In an example, the red light emitting unit 31 for emitting the red light, the green light emitting unit 31 for emitting the green light, and the blue light emitting unit 31 for emitting the blue light are arranged in rows along the first direction X, and the rows arranged by the light emitting units are spaced apart along the second direction Y. The first opening 24 is disposed on a side of the light emitting unit 31 along the second direction Y. The first projection is distributed on one side of the first opening 24 along the second direction Y, and the first projection is not distributed on the other side of the first opening 24 along the second direction Y.

Referring to FIG. 12, in some embodiments, at least a part of the first projection surrounds a third boundary line 2413 and a fourth boundary line 2414 of the first opening 24, and a minimum distance of the first projection to the third boundary line 2413 is not the same as a minimum distance of the first projection to the fourth boundary line 2414.

The third boundary line 2413 and the fourth boundary line 2414 are the boundary lines extending in different directions. Since the distance between the first opening 24 and one adjacent isolation opening 23 and the distance between the first opening 24 and the other adjacent isolation opening 23 are different, the minimum distance of the first projection to the third boundary line 2413 is not the same as the minimum distance of the first projection to the fourth boundary line 2414. Therefore, the minimum distance of the first projection to the isolation opening 23 may be greater than a preset threshold, thereby preventing the touch wiring 41 from affecting the light emitting of the light emitting unit 31 in the isolation opening 23.

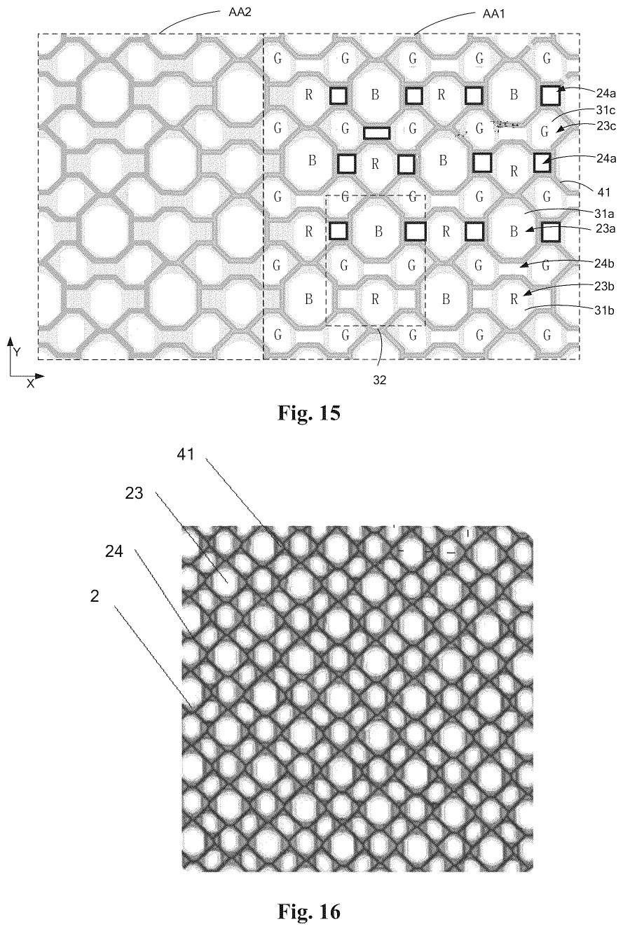

Referring to FIGS. 14 and 15, in some embodiments, the display panel includes a first display region AA1 and a second display region AA2, and the plurality of first openings 24 are distributed in the first display region AA1. For example, the plurality of first openings 24 are distributed only in the first display region AA1. For example, the plurality of first openings 24 are distributed not only in the first display region AA1, but also in the second display region AA2, and the arrangement of the plurality of first openings 24 in the first display region AA1 is the same as the arrangement of the plurality of first openings 24 in the second display region AA2.

The display region AA is used for achieving a screen display, and the display region AA includes the first display region AA1 and the second display region AA2. Compared to the second display region AA2, the first display region AA1 may be used to allow the light to pass through to the light sensor. The first display region AA1 may be a display region with a light sensor set below. The light sensor can be either a camera or an infrared sensor. The first display region AA1 is the hole region of the display panel. The relevant components can be set under the screen of the first display region AA1, for example, an optical sensor may be provided, and the optical sensor receives the light passing through from the first display region AA1 and completes the camera function.

At least a part of the first opening 24 is located in the first display region AA1. The first opening 24 is provided in the first display region AA1 to increase the light transmittance of the first display region AA1. The light emitting unit 31 is distributed in the display region, so that the display region can display light emitting. The first opening 24 is mainly provided in the first display region AA1, and the external light can irradiate the optical sensor through the first opening 24. The touch wiring 41 may be distributed in the display region, so that the display region can realize touch function. Optionally, the light transmittance of the display panel in the first display region AA1 is greater than or equal to 0.5%, so that the light sensor disposed on the side of the first display region AA1 can receive a sufficient amount of light.

In some embodiments, a pattern of the touch wiring 41 located in the second display region AA2 is the same pattern as the touch wiring 41 located in the first display region AA1; a pixel arrangement of the second display region AA2 is the same as a pixel arrangement of the first display region AA1.

The patterns of the touch wirings 41 being the same may be that the orthographic projections of the touch wirings 41 enclosing and forming the meshes 42 on the array substrate 1 are the same. That is, the orthographic projection of the mesh 42 of the first display region AA1 on the array substrate 1 is the same as the orthographic projection of the mesh 42 of the second display region AA2 on the array substrate 1. The pixel arrangement of the second display region AA2 is the same as the pixel arrangement of the first display region AA1, that is, the compositions and arrangements of the light emitting pixel groups 32 are the same. By setting the pattern of the touch wirings located in the second display region AA2 as being the same as the pattern of the touch wirings located in the first display region AA1; and by setting the pixel arrangement of the second display region AA2 as being the same as the pixel arrangement of the first display region AA1, the first display region AA1 and the second display region AA2 are consistent in the display and non-display states, thereby avoiding or reducing the uneven brightness of the display panel.

In some embodiments, a distribution density of the touch wirings 41 in the first display region AA1 is less than a distribution density of the touch wirings 41 in the second display region AA2. That is, in a unit area, the area of the orthographic projection of the touch wirings 41 in the first display region AA1 on the array substrate 1 is less than the area of the orthographic projection of the touch wirings 41 in the second display region AA2 on the array substrate 1.

The arrangement of the touch wirings 41 in the second display region AA2 is shown in FIG. 16, and the arrangement of the touch wirings 41 in the first display region AA1 is shown in FIG. 3. The touch wirings 41 may include a touch receiving wiring and a touch transmitting wiring, and the touch receiving wiring and the touch transmitting wiring may cooperate to realize the touch function of the display panel. In this embodiment, the distribution density of the touch wirings 41 in the first display region AA1 is less than the distribution density of the touch wirings 41 in the second display region AA2. For example, the distribution density of the touch wirings 41 in the second display region AA2 is substantially the same as the distribution density of the touch wirings 41 in the display function region in the related technique, and the distribution density of the touch wirings 41 in the first display region AA1 is less than the distribution density of the touch wiring 41 in the hole region in the related technique. Therefore, this embodiment reduces the distribution number of the touch wirings 41 in the first display region AA1, and differentiates the distribution densities of the touch wirings 41 in the first display region AA1 and the second display region AA2, which can greatly reduce the problem that the touch wirings 41 block the light from reaching the components of the first display region AA1, and can improve the light transmittance of the first display region AA1, thus improving the reliability of the components provided in the first display region AA1.

Based on the above design, by setting the distribution density of the touch wirings 41 in the first display region AA1 as being less than the distribution density of the touch wirings 41 in the second display region AA2, this embodiment can improve the light transmittance of the first display region AA1, and can reduce the interference between the touch wirings 41 and the signal lines in the array substrate 1, thereby improving the reliability of the display panel.

Referring to FIG. 15, in some embodiments, the touch wiring 41 includes a plurality of straight segments, orthographic projections of at least two of the straight segments on the array substrate 1 are at the same distance to the orthographic projection of the isolation opening 23 on the array substrate 1.

The straight segments may extend along the boundary lines of the first opening 24 and the isolation opening 23. Optionally, the straight segments are located between the red light emitting unit 31b and the green light emitting unit 31c, and the straight segments are located between the blue light emitting unit 31a and the green light emitting unit 31c. By setting the straight segments as being at the same distance to the isolation opening 23, the color bias may be avoided or reduced, and the display effect may be improved.

In some embodiments, the minimum spacing between the orthographic projection of the first opening 24 on the array substrate 1 and the orthographic projection of the touch wiring 41 on the array substrate 1 is greater than or equal to 50 μm, so as to avoid preparing the offset touch wiring 41 that blocks the first opening 24.

In some embodiments, the first opening 24 is located between the adjacent isolation openings 23. Optionally, the isolation structure 2 is in a mesh shape, the isolation openings 23 are arranged in an array, and the first opening 24 is arranged between the adjacent isolation openings 23.

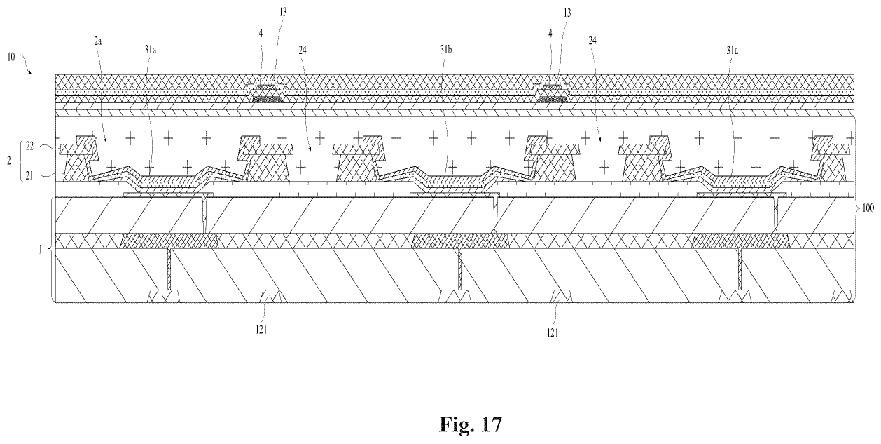

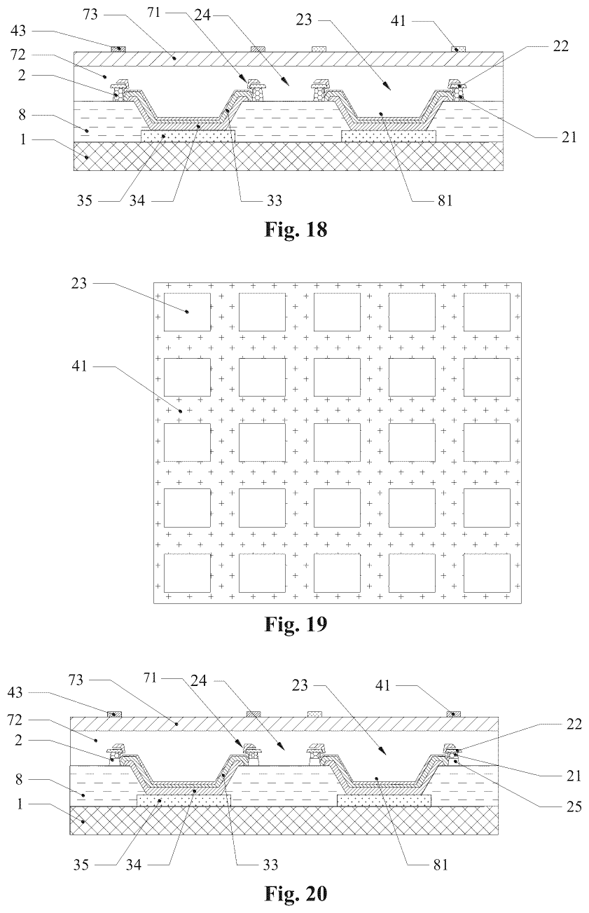

Referring to FIGS. 17 and 18, it should be noted that the isolation structure 2 refers to a “large top and small bottom” undercut structure capable of separating the light emitting material of the adjacent light emitting units. The isolation structure 2 can be either a structure formed by a single membrane layer, or a structure formed by multiple membrane layers that are stacked. For example, under a condition that the isolation structure 2 is a single layer structure, the sectional shape of the isolation structure 2 can be an inverted trapezoid of “large top and small bottom”. In some embodiments, the isolation structure 2 includes a first portion 21 and a second portion 22 that are stacked, the first portion 21 is provided on a side of the second portion 22 close to the array substrate 1, and the orthographic projection of the first portion 21 on the array substrate 1 is within the orthographic projection of the second portion 22 on the array substrate 1.

The isolation structure 2 encloses and forms the isolation opening 23, so as to define the setting range of the light emitting function layer, the isolation structure 2 includes the first portion 21 and the second portion 22 that are stacked, and the orthographic projection of the first portion 21 on the array substrate 1 is located within the orthographic projection of the second portion 22 on the array substrate 1, so that the cross-sectional area of the end of the isolation structure 2 away from the array substrate 1 is relatively large, and the cross-sectional area of the end of the isolation structure 2 close to the array substrate 1 is relatively small. In the direction from the isolation structure 2 to the array substrate 1, the second portion 22 completely blocks the first portion 21.

When preparing the light emitting unit 31, the light emitting material A for preparing the light emitting unit 31 may cover on the isolation structure 2 based on the evaporation technique. Since the second portion 22 blocks the first portion 21, the light emitting material A for preparing the light emitting unit 31 creates a large drop in the boundary line of the second portion 22, and the light emitting material A falling in the isolation opening 23 and the light emitting material A falling on the second portion 22 are difficult to connect with each other, thus breaking to form the light emitting material A disposed in the adjacent isolation opening 23. The light emitting material A falling on the second portion 22 may be removed as required. In contrast to the light emitting function layer prepared by mask evaporation in the relevant art, the first portion 21 and the second portion 22 are provided in the present application, so that the light emitting unit 31 is prepared in the isolation opening 23 without the metal mask, thus eliminating the cost of preparing the metal mask. Compared with the evaporation preparation of the light emitting function layer using a high precision metal mask, it is easier to directly prepare the high precision isolation structure 2, so that the structure of the display panel provided in the present application has low requirements on the preparation process, and the consistency of the display panel is good. The light emitting material can be a complex containing indium elements.

In some embodiments, the area of the orthographic projection of the surface of the second portion 22 away from the array substrate 1 on the array substrate 1 is less than the area of the orthographic projection of the surface of the second portion 22 close to the array substrate 1 on the array substrate 1.

The second portion 22 extends outward a predetermined distance relative to the first portion 21, that is, the area of the orthographic projection of the surface of the second portion 22 away from the array substrate 1 on the array substrate 1 is less than the area of the orthographic projection of the surface of the second portion 22 close to the array substrate 1 on the array substrate 1, so that the second portion 22 has an inclined slope structure to define the pattern of the light emitting function layer through the second portion 22.

In some embodiments, the cross-sectional area of the second portion 22 gradually decreases in the direction away from the array substrate 1.

The cross section of the second portion 22 may be a trapezoid with the bottom edge facing the array substrate 1, so that the second portion 22 has a sloping surface, which is beneficial to the break of the prepared material at the separated boundary line, thereby forming a state that a part of the prepared material is located on the second portion 22 and another part of the prepared material is located in the isolation opening 23.

In some embodiments, the area of the orthographic projection of the surface of the first portion 21 away from the array substrate 1 on the array substrate 1 is less than the area of the orthographic projection of the surface of the second portion 22 close to the array substrate 1 on the array substrate 1

That is, the second portion 22 extends outward relative to the first portion 21, so as to limit the pattern of the light emitting function layer through the second portion 22. The orthographic projection of the first portion 21 on the array substrate 1 is located within the orthographic projection of the second portion 22 on the array substrate 1, and at this time, the first portion 21 is depressed against the second portion 22 toward a direction away from the isolation opening 23. When preparing the light emitting function layer, the light emitting function layer has a large drop at the edge of the isolation structure 2, and the first portion 21 is concave, and the light emitting function layer is difficult to be connected outside the isolation structure 2, thus breaking and forming the isolated light emitting function layer.

In some embodiments, the light emitting unit 31 includes a first electrode 33 and a light emitting layer 34, a side of the first electrode 33 close to the array substrate 1 is connected to the light emitting layer 34, and the edge of the first electrode 33 contacts and overlaps with the isolation structure 2.

The first electrode 33 may be a cathode or an anode, and the first electrode 33 is connected to the light emitting layer 34 to drive the light emitting layer 34 to emit light. Under a condition that the first electrode 33 is a cathode, the isolation structure 2 transmits a VSS signal, and under a condition that the first electrode 33 is an anode, the isolation structure 2 transmits a VDD signal.

The light emitting layer 34 includes at least an emission layer (EML). Further, the light emitting layer 34 can also include one or more of a hole injection layer (HIL), a hole transport layer (HTL), an electron injection layer (EIL), an electron transport layer (ETL), a hole block layer (HBL) and an electron block layer (EBL). Alternatively, the light emitting function portion may be a light emitting structure having stacked layers, which may include at least two light emitting layers and a charge generation layer (CGL) located between the adjacent light emitting layers.

In one of these examples, the first portion 21 includes at least one metal layer. In one example, the material of the first portion 21 includes at least one of a metal and a metal oxide. Exemplarily, the metal can be silver, copper, titanium, aluminum, and the like. The metal oxide can be tin oxide, zinc oxide, cadmium oxide, indium oxide, indium tin oxide, zinc indium oxide, zinc gallium oxide, zinc aluminum oxide, tantalum titanium oxide, and the like.

In one of these examples, the isolation structure 2 further includes a bearing portion disposed between the array substrate 1 and the first portion 21.

In one example, the bearing portion includes a conductive material. Thus, it is advantageous to further reduce the resistance of the isolation structure 2, thereby reducing the power consumption of the display panel 100.

In some embodiments, the edge of the first electrode 33 contacts and overlaps with the isolation structure 2.

The edge of the first electrode 33 contacts and overlaps with the isolation structure 2, and the isolation structure 2 can supply power to the first electrode 33 and conduct the adjacent first electrode 33, thus forming the surface electrode with the whole surface being conductive.

Under a condition that the first electrode 33 contacts and overlaps with the isolation structure 2 to form the surface electrode, the touch layer 4 may be shielded from the driving circuit layer 12 by the surface electrode.

In some embodiments, the light emitting unit 31 includes a plurality of second electrodes 35 that are located on a side of the light emitting layer 34 close to the array substrate 1. The light emitting unit 31 includes a second electrode 35, a light emitting layer 34 and a first electrode 33 located at least partially in the isolation opening 23 and stacked in sequence in a direction away from the array substrate 1. For the first electrode 33 and the second electrode 35, one may act as an anode electrode and the other may as a cathode electrode. The first electrode 33, the light emitting layer 34 and the second electrode 35 may be contacted and stacked in sequence in the third direction Z, thereby realizing the electrical conduction of the first electrode 33, the light emitting layer 34 and the second electrode 35. Optionally, the first electrode 33 is a cathode electrode, and the second electrode 35 is an anode electrode.

Optionally, referring to FIG. 19 and FIG. 20, an orthographic projection of the isolation structure 2 on the array substrate 1 forms a net structure. Thus, the isolation structure 2 can better partition the second electrode layer to form the first electrodes 33 that are spaced apart and separately located in the isolation openings 23.

In some possible implementations, referring again to FIG. 18, the first electrode 33 of the light emitting unit 31 is electrically connected to the first portion 21; referring to FIG. 20, and/or, the isolation structure 2 further includes a third portion 25 located at a side of the first portion 21 facing the array substrate 1, the first electrode 33 of the light emitting unit 31 is electrically connected to the third portion 25; the material of the third portion 25 includes molybdenum metal; and/or the material of the first portion 21 includes aluminum metal; and/or the material of the second portion 22 includes titanium metal.

In some embodiments, the display panel also includes a pixel definition layer 8 arranged between the array substrate 1 and the isolation structure 2, the pixel definition layer 8 includes a pixel opening 81, the pixel opening 81 is communicated to the isolation opening 23, and the orthographic projection of the pixel opening 81 on the array substrate 1 is located within the orthographic projection of the isolation opening 23 on the array substrate 1.

The pixel definition layer 8 is located on one side of the array substrate 1, and the pixel definition layer 8 encloses and forms the pixel opening 81. The light emitting unit 31 may be at least partially provided in the pixel opening 81 to achieve a light emitting display of the display panel, and the pixel opening may be arranged corresponding to the isolation opening 23.

In some embodiments, the isolation structure 2 is disposed on a side of the pixel definition layer 8 away from the array substrate 1, and the light emitting function layer is at least partially disposed within the pixel opening 81.

The isolation structure 2 is provided on the side of the pixel definition layer 8 away from the array substrate 1, and the orthographic projection of the pixel opening 81 on the array substrate 1 is located in the orthographic projection of the isolation opening 23 on the array substrate 1. The isolation structure 2 may be provided directly on the side of the pixel definition layer 8 away from the array substrate 1, and the isolation structure 2 may be supported by the pixel definition layer 8. The orthographic projection of the pixel opening 81 on the array substrate 1 may be located in the orthographic projection of the isolation opening 23 on the array substrate 1. The area of the isolation opening 23 is greater than the area of the pixel opening 81, thereby reducing the influence of the isolation structure 2 on the light viewing angle of the light emitting function layer.

Optionally, there may be a plurality of pixel openings 81, the plurality of pixel openings 81 are spaced apart, and the isolation structure 2 may be provided on the pixel definition layer 8 between two adjacent pixel openings 81 of at least a part of the pixel openings 81. Optionally, the isolation structure 2 may be disposed around at least a part of the pixel openings 81.

At least a part of the first electrodes 33 extend from the pixel opening 81 to the side of the pixel definition layer 8 away from the array substrate 1, and electrically contact with the third portion 25 or the first portion 21 of the isolation structure 2, the third portion 25 or the first portion 21 of the isolation structure 2 may connect the adjacent first electrodes 33 or connect the first electrode 33 to other circuits, thus facilitating the isolation structure 2 to partition the second electrode layer to form the first electrodes 33 and electrically connect the first electrodes 33.

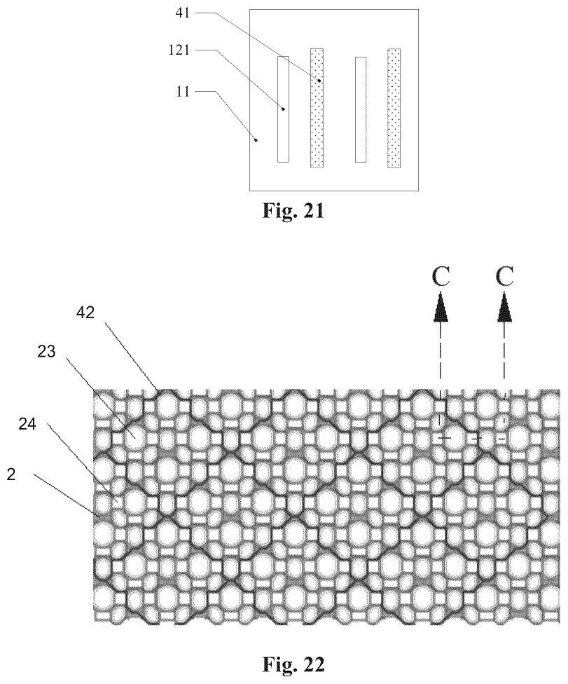

In some possible implementations, referring to FIG. 21, the array substrate 1 includes a substrate 11 and a signal wiring 121 located on a side of the substrate 11, and the orthographic projection of the touch wiring 41 on the substrate 11 does not overlap with the orthographic projection of the signal wiring 121 on the substrate 11.

The array substrate 1 includes data lines (data) and/or scanning lines (scan), and the like, and the voltage jump of the signal wirings 121 can affect the touch accuracy of the touch wiring 41. Accordingly, setting that the orthographic projection of the touch wiring 41 on the substrate 11 does not overlap with the orthographic projection of the signal wiring 121 on the substrate 11 may reduce the influence of the signal wiring 121 on the touch wiring 41.

In some possible implementations, referring to FIG. 2, the display panel further includes a first encapsulation layer 71 located on a side of the first electrode 33 away from the array substrate 1, the first encapsulation layer 71 includes a plurality of encapsulation units 711, and an orthographic projection of the encapsulation unit 711 on the array substrate 1 covers an orthographic projection of the light emitting unit on the array substrate 1.

The first encapsulation layer 71 is an inorganic encapsulation layer, the isolation structure 2 includes a side close to the array substrate 1, a side away from the array substrate 1, and a side surface, each independent encapsulation unit 711 extends from the side wall of the isolation structure 2 to the side of the isolation structure 2 away from the array substrate 1, and the encapsulation unit 711 is in contact with the side wall of the isolation structure 2 and the surface of the isolation structure 2 away from the array substrate 1, and the encapsulation units 711 are spaced apart at the side of the isolation structure 2 away from the array substrate 1. In this way, the independent encapsulation effect of pixels can be greatly improved, so that the optical performance of the display panel can be further optimized.

Optionally, referring to FIG. 20, the display panel further includes a second encapsulation layer 72 located on a side of the first encapsulation layer 71 away from the array substrate 1; and a side of the second encapsulation layer 72 away from the array substrate 1 has a flat surface.

The second encapsulation layer 72 is an organic encapsulation layer, the second encapsulation layer 72 can be formed by inkjet printing, and the second encapsulation layer 72 can fill the side of the isolation structure 2 away from the array substrate 1, the isolation opening 23 and the first opening 24, which can better protect the light emitting unit 31.

Optionally, referring to FIG. 18, the display panel further includes a third encapsulation layer 73 located on a side of the second encapsulation layer 72 away from the array substrate 1, and the touch layer 4 is located on a side of the third encapsulation layer 73 away from the array substrate 1. The third encapsulation layer 73 is an inorganic encapsulation layer, and the third encapsulation layer 73 may further improve the encapsulation effect of the light emitting unit 31.

In some possible implementations, please refer to FIG. 1 again, the adjacent touch wirings 41 in the touch layer 4 are connected to form a mesh 42, and the orthographic projection of the isolation opening 23 and/or the first opening 24 on the array substrate 1 at least partially overlaps with the orthographic projection of a mesh hole of the mesh 42 on the array substrate 1.

The touch wirings 41 are interconnected to form a mesh 42 including a plurality of mesh holes, and by setting that the orthographic projection of the mesh hole on the array substrate 1 at least partially overlaps with the orthographic projection of the isolation opening 23 and/or the first opening 24 on the array substrate 1, the light transmittance of the isolation opening 23 and/or the first opening 24 may be increased.

In some possible implementations, please refer to FIG. 1 again, the orthographic projection of at least one isolation opening 23 and/or at least one first opening 24 on the array substrate 1 is located within an orthographic projection of a mesh hole of the mesh 42 on the array substrate 1. The area of the orthographic projection of the mesh hole on the array substrate 1 is greater than the area of the orthographic projection of the isolation opening 23 and/or the first opening 24 on the array substrate 1, so that the orthographic projection of the mesh hole on the array substrate 1 may cover the orthographic projection of at least one isolation opening 23 and/or at least one first opening 24 on the array substrate 1. Thus, the density of the mesh holes of the mesh 42 of the touch wirings 41 may be reasonably arranged according to the isolation opening 23 and/or the first opening 24.

Optionally, please refer to FIG. 1 again, the area of the orthographic projection of the mesh hole of the mesh 42 in the second display region AA2 on the array substrate 1 is less than the area of the orthographic projection of the mesh hole of the mesh 42 in the first display region AA1 on the array substrate 1. Thus, under a condition that the arrangements of the touch wirings 41 in the first display region AA1 and the second display region AA2 are substantially the same, by setting the density of the mesh holes of the mesh 42 in the second display region AA2 as being smaller than the density of the mesh holes of the mesh 42 in the first display region AA1, the light transmittance of the first display region AA1 can be improved.

Optionally, the ratio of the area of the orthographic projection of the mesh hole of the mesh 42 in the second display region AA2 on the array substrate 1 to the area of the orthographic projection of the mesh hole of the mesh 42 in the first display region AA1 on the array substrate 1 is ½ to 1/16, for example, ½, ¼, ⅛ or 1/16, and the like. By reasonably setting the proportion of the density of the mesh holes of the mesh 42 in the second display region AA2 to the density of the mesh holes of the mesh 42 in the first display region AA1, it can not only increase the light transmittance of the first display region AA1, but also minimize the difference in the densities of the touch wirings 41 in the first display region AA1 and the second display region AA2, thereby improving the display uniformity of the display panel.

For example, in some embodiments, please refer to FIG. 3 again, the ratio of the area of the orthographic projection of the mesh hole of the mesh 42 in the second display region AA2 on the array substrate 1 to the area of the orthographic projection of the mesh hole of the mesh 42 in the first display region AA1 on the array substrate 1 is ½.

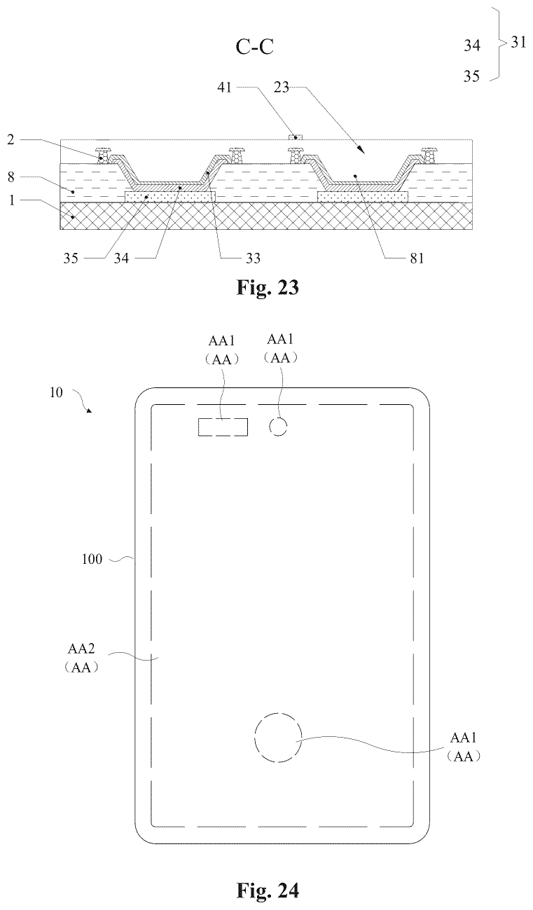

In other embodiments, please refer to FIG. 22 to FIG. 23, the ratio of the area of the orthographic projection of the mesh hole of the mesh 42 in the second display region AA2 on the array substrate 1 to the area of the orthographic projection of the mesh hole of the mesh 42 in the first display region AA1 on the array substrate 1 is ¼. As shown in FIG. 22, a plurality of isolation openings 23 and a plurality of first openings 24 are provided in the mesh 42.

In conclusion, by setting the distribution density of the touch wirings 41 in the first display region AA1 as being less than the distribution density of the touch wirings 41 in the second display region AA2, it can improve the light transmittance of the first display region AA1 and reduce the mutual interference between the touch wirings 41 and the signal lines in the array substrate 1, thereby improving the reliability of the display panel.

The embodiments of a second aspect of the present application further provides a display panel. Please refer to FIG. 1 to FIG. 23 again, the display panel includes an array substrate 1, an isolation structure 2, a light emitting function layer and a touch layer 4. The isolation structure 2 is disposed on a side of the array substrate 1, and the isolation structure 2 is provided with a plurality of isolation openings 23 and a plurality of first openings 24; the light emitting function layer includes a plurality of light emitting units 31, at least a part of the light emitting unit 31 is disposed within the isolation opening 23; the touch layer 4 is disposed on a side of the isolation structure 2 away from the array substrate 1, the touch layer 4 includes a plurality of touch wirings 41, an orthographic projection of the touch wiring 41 on the array substrate 1 is located within an orthographic projection of the isolation structure 2 on the array substrate 1, an orthographic projection of the touch wiring 41 on the isolation structure 2 is a first projection, and the first projection is not distributed between at least one isolation opening 23 and the first opening 24 adjacent to the at least one isolation opening 23.

The array substrate 1, the isolation structure 2, the light emitting function layer and the touch layer 4 provided in the second aspect may be referred to the arrangement of the array substrate 1, the isolation structure 2, the light emitting function layer and the touch layer 4 provided in the first aspect, which will not be repeated here.

In the embodiments provided by the present application, by setting the first openings 24, the light transmittance of the display panel may be improved; by setting the orthographic projection of the touch wiring 41 on the array substrate 1 as being located within the orthographic projection of the isolation structure 2 on the array substrate 1, the problem that the touch layer 4 blocks the light entering the first openings 24 or blocks the light exiting the isolation openings 23 may be avoided or reduced, and the light transmittance of the display panel may be improved; by setting the first projection as being not distributed between at least one isolation opening 23 and the first opening 24 adjacent to the at least one isolation opening 2, it is beneficial to increase the size of the first opening 24 and improve the light transmittance.

In some embodiments, the plurality of light emitting units 31 include a first light emitting unit 31a for emitting a first color light and a second light emitting unit 31b for emitting a second color light, the plurality of isolation openings 23 include a first isolation opening 23a and a second isolation opening 23b, at least a part of the first light emitting unit 31a is located within the first isolation opening 23a, and at least a part of the second light emitting unit 31b is located within the second isolation opening 23b;

the plurality of first openings 24 include a plurality of first sub-openings 24a, the first sub-opening 24a is disposed between the first isolation opening 23a and the second isolation opening 23b adjacent to the first isolation opening 23a in a first direction X.

The first color light may be a blue light, the second color light may be a red light, the first light emitting unit 31a is used to emit the blue light, and the second light emitting unit 31b is used to emit the red light. A plurality of first light emitting units 31a and a plurality of second light emitting units 31b may be arranged alternately along the first direction X, and a plurality of first sub-openings 24a may be spaced apart along the first direction X and may be disposed between the first light emitting unit 31a and the second light emitting unit 31b adjacent to the first light emitting unit 31a. Therefore, the external light may inject from one side of the display panel through the first sub-opening 24a between the first light emitting unit 31a and the second light emitting unit 31b.

Optionally, the touch wiring 41 is distributed between the first sub-opening 24a and the first light emitting unit 31a, the touch wiring 41 is not distributed between the first sub-opening 24a and the second light emitting unit 31b, and a projection area of the first isolation opening 23a on the array substrate 1 is greater than a projection area of the second isolation opening 23b on the array substrate 1.

Since the projection area of the first isolation opening 23a on the array substrate 1 is greater than the projection area of the second isolation opening 23b on the array substrate 1, a projection area of the first light emitting unit 31a located in the first isolation opening 23a on the array substrate 1 may be larger than a projection area of the second light emitting unit 31b located in the second isolation opening 23b on the array substrate 1. The touch wiring 41 is distributed between the first sub-opening 24a and the first light emitting unit 31a, and the touch wiring 41 is not distributed between the first sub-opening 24a and the second light emitting unit 31b. Therefore, compared to the first light emitting unit 31a, the second light emitting unit 31b has a larger light emitting angle, which is advantageous to increase the light emitting rate of the second light emitting unit 31b.

In some embodiments, the plurality of light emitting units 31 further include a third light emitting unit 31c for emitting a third color light, the plurality of isolation openings 23 further comprise a third isolation opening 23c, at least a part of the third light emitting unit 31c is located in the third isolation opening 23c; the plurality of first openings 24 further include a plurality of second sub-openings 24b, the second sub-opening 24b is disposed between adjacent third isolation openings 23c.

The third color light may be a green light, and the third light emitting unit 31c is used to emit the green light. The third isolation openings 23c may be spaced apart along the second direction Y, and the second sub-opening 24b may be disposed between the adjacent third isolation openings 23c along the first direction X. By providing the second sub-opening 24b between the third isolation openings 23c, the light transmittance between the third light emitting units 31c may be increased.

The first isolation opening 23a and the second isolation opening 23b are arranged along the second direction Y, and the second sub-opening 24b is located between the first isolation opening 23a and the second isolation opening 23b that are arranged along the second direction Y. The touch wiring 41 is distributed between the second sub-opening 24b and the first isolation opening 23a and between the second sub-opening 24b and the second isolation opening 23b, and the touch wiring 41 is not distributed between the second sub-opening 24b and the third light emitting unit 31c adjacent to the second sub-opening 24b, which is beneficial to increase the length of the third isolation opening 23c along the first direction X, and increase the size or distribution density of the third light emitting unit 31c.

Optionally, the projection area of the third isolation opening 23c on the array substrate 1 is less than the projection area of the first isolation opening 23a on the array substrate 1, and less than the projection area of the second isolation opening 23b on the array substrate 1, so that the projection area of the third light emitting unit 31c located in the third isolation opening 23c on the array substrate 1 is less than the projection area of the first light emitting unit 31a located in the first isolation opening 23a on the array substrate 1, and less than the projection area of the second light emitting unit 31b located in the second isolation opening 23b on the array substrate 1. Further, the touch wiring 41 is distributed between the second sub-opening 24b and the first isolation opening 23a, and between the second sub-opening 24b and the second isolation opening 23b, and the touch wiring 41 is not distributed between the second sub-opening 24b and the third light emitting unit 31c adjacent to the second sub-opening 24b. Therefore, compared to the first light emitting unit 31a and the second light emitting unit 31b, the third light emitting unit 31c has a larger light emitting angle, which is advantageous to increase the light emitting rate of the third light emitting unit 31c.

In some embodiments, the touch wirings 41 enclose and form a plurality of meshes 42, the plurality of meshes 42 correspond to a plurality of mesh regions in a one to one relationship, at least one of the mesh regions is provided with the isolation opening 23 and the first opening 24 adjacent to the isolation opening 23;

the touch wirings 41 enclosing and forming two adjacent meshes 42 have a common touch wiring 41.

One mesh region 42 may be provided with one pixel light emitting group 32. For example, one first light emitting unit 31a, one second light emitting unit 31b, and two third light emitting units 31c form one pixel light emitting group 32, and the pixel light emitting group 32 is disposed in the mesh enclosed and formed by the touch wiring 41. The mesh 42 can be repeatedly laid, thereby simplifying the design of the touch wiring 41. The touch wirings 41 enclosing and forming two adjacent mesh regions 42 have a common touch wiring 41, thereby increasing the proportion of the touch wirings 41 distributed between the adjacent isolation openings 23, and reducing the space occupied by the touch wirings 41 between the adjacent isolation openings 23, which helps to increase the size or distribution density of the isolation openings 23.

In some embodiments, the plurality of isolation openings 23 include a first isolation opening 23a, the plurality of the light emitting units 31 include a first light emitting unit 31a for emitting a first color light, at least a part of the first light emitting unit 31a is located within the first isolation opening 23a; a first projection of the touch wirings 41 enclosing and forming at least one of the mesh regions 42 surrounds an entire boundary of the first isolation opening 23a;

the plurality of isolation openings 23 include a second isolation opening 23b, the plurality of light emitting units 31 comprise a second light emitting unit 31b for emitting a second color light, at least a part of the second light emitting unit 31b is located within the second isolation opening 23b, and at least one of the mesh regions 42 is provided with the second isolation opening 23b and the first openings 24 on two opposite sides of the second isolation opening 23b;

the plurality of the isolation openings 23 include a third isolation opening 23c, the plurality of light emitting units 31 include a third light emitting unit 31c for emitting a third color light, at least a part of the third light emitting unit 31c is located in the third isolation opening 23c; and at least one of the mesh regions 42 is provided with the first opening 24 and third isolation openings 23c on two opposite sides of the first opening 24.

The boundary line of the second isolation opening 23b facing the first isolation opening 23a along a first direction X is not surrounded by the first projection of the touch wiring 41, which is beneficial to increase the length of the second isolation opening 23b along the first direction X, and increase the size or distribution density of the second light emitting unit 31b. The third isolation openings 23c are disposed on two opposite sides of the first opening 24, so as to increase the light transmittance in the mesh region 42, and increase the light transmission uniformity in the mesh region.

The embodiments of a third aspect of the present application further provides a display panel. Please refer to FIG. 1 to FIG. 23 again, the display panel includes an array substrate 1, an isolation structure 2, a light emitting function layer and a touch layer 4. The isolation structure 2 is disposed on a side of the array substrate 1, and the isolation structure 2 is provided with a plurality of isolation openings 23 and a plurality of first openings 24; the light emitting function layer includes a plurality of light emitting units 31, at least a part of the light emitting unit 31 is disposed within the isolation opening 23; the touch layer 4 is disposed on a side of the isolation structure 2 away from the array substrate 1, the touch layer 4 includes a plurality of touch wirings 41, the touch wirings 41 enclose and form a plurality of meshes 42, and a mesh region corresponding to at least one of the meshes 42 is provided with the isolation opening 23 and the first opening 24.

The array substrate 1, the isolation structure 2, the light emitting function layer and the touch layer 4 provided in the third aspect may be referred to the arrangement of the array substrate 1, the isolation structure 2, the light emitting function layer and the touch layer 4 provided in the first aspect, which will not be repeated here.

The plurality of meshes 42 may correspond to a plurality of mesh regions in a one to one relationship. One mesh region 42 may be provided with one pixel light emitting group 32. For example, one first light emitting unit 31a, one second light emitting unit 31b, and two third light emitting units 31c form one pixel light emitting group 32, and the pixel light emitting group 32 is disposed in the mesh enclosed and formed by the touch wiring 41. The mesh 42 can be repeatedly laid, thereby simplifying the design of the touch wiring 41. The touch wirings 41 enclosing and forming two adjacent mesh regions 42 have a common touch wiring 41, thereby increasing the proportion of the touch wirings 41 distributed between the adjacent isolation openings 23, and reducing the space occupied by the touch wirings 41 between the adjacent isolation openings 23, which helps to increase the size or distribution density of the isolation openings 23.

In the embodiments provided by the present application, by setting the first openings 24, the light transmittance of the display panel may be improved; by setting the orthographic projection of the touch wiring 41 on the array substrate 1 as being located within the orthographic projection of the isolation structure 2 on the array substrate 1, the problem that the touch layer 4 blocks the light entering the first openings 24 or blocks the light exiting the isolation openings 23 may be avoided or reduced, and the light transmittance of the display panel may be improved; by setting the isolation opening 23 and the first opening 24 in the corresponding mesh region of the mesh 42, the light transmittance of the corresponding region of the mesh 42 is improved.

In some embodiments, the plurality of light emitting units 31 comprise a second light emitting unit 31b for emitting a second color light, the plurality of isolation openings 23 include a second isolation opening 23b, at least a part of the second light emitting unit 31b is located within the second isolation opening 23b, and at least one of the mesh regions 42 is provided with the second isolation opening 23b and the first openings 24 on two opposite sides of the second isolation opening 23b;

the orthographic projection of the touch wiring 41 on the isolation structure 2 is the first projection, and in the corresponding mesh region of a same mesh region 42, the first projection is not distributed between the second isolation opening 23b and the first opening 24 adjacent to the second isolation opening 23b.

The boundary line of the second isolation opening 23b facing the first isolation opening 23a along a first direction X is not surrounded by the first projection of the touch wiring 41, which is beneficial to increase the length of the second isolation opening 23b along the first direction X, and increase the size or distribution density of the second light emitting unit 31b. The third isolation openings 23c are disposed on two opposite sides of the first opening 24, so as to increase the light transmittance in the mesh region 42, and increase the light transmission uniformity in the mesh region.

In some embodiments, the plurality of the isolation openings 23 include a third isolation opening 23c, the plurality of light emitting units 31 include a third light emitting unit 31c for emitting a third color light, at least a part of the third light emitting unit 31c is located in the third isolation opening 23c; and at least one of the mesh regions 42 is provided with the first opening 24 and third isolation openings 23c on two opposite sides of the first opening 24.

The orthographic projection of the touch wiring 41 on the isolation structure 2 is the first projection, and in the corresponding mesh region of a same mesh region 42, the first projection is not distributed between the third isolation opening 23c and the first opening 24 adjacent to the third isolation opening 23c.

The first color light may be a blue light, the second color light may be a red light, the first light emitting unit 31a is used to emit the blue light, and the second light emitting unit 31b is used to emit the red light. A plurality of first light emitting units 31a and a plurality of second light emitting units 31b may be arranged alternately along the first direction X, and a plurality of first sub-openings 24a may be spaced apart along the first direction X and may be disposed between the first light emitting unit 31a and the second light emitting unit 31b adjacent to the first light emitting unit 31a. Therefore, the external light may inject from one side of the display panel through the first sub-opening 24a between the first light emitting unit 31a and the second light emitting unit 31b.

Optionally, the touch wiring 41 is distributed between the first sub-opening 24a and the first light emitting unit 31a, the touch wiring 41 is not distributed between the first sub-opening 24a and the second light emitting unit 31b, and a projection area of the first isolation opening 23a on the array substrate 1 is greater than a projection area of the second isolation opening 23b on the array substrate 1.

Since the projection area of the first isolation opening 23a on the array substrate 1 is greater than the projection area of the second isolation opening 23b on the array substrate 1, a projection area of the first light emitting unit 31a located in the first isolation opening 23a on the array substrate 1 may be larger than a projection area of the second light emitting unit 31b located in the second isolation opening 23b on the array substrate 1. The touch wiring 41 is distributed between the first sub-opening 24a and the first light emitting unit 31a, and the touch wiring 41 is not distributed between the first sub-opening 24a and the second light emitting 31b has a larger light emitting angle, which is advantageous to increase the light emitting rate of the second light emitting unit 31b.

In some embodiments, the plurality of light emitting units 31 further include a third light emitting unit 31c for emitting a third color light, the plurality of isolation openings 23 further comprise a third isolation opening 23c, at least a part of the third light emitting unit 31c is located in the third isolation opening 23c; the plurality of first openings 24 further include a plurality of second sub-openings 24b, the second sub-opening 24b is disposed between adjacent third isolation openings 23c.

The third color light may be a green light, and the third light emitting unit 31c is used to emit the green light. The third isolation openings 23c may be spaced apart along the second direction Y, and the second sub-opening 24b may be disposed between the adjacent third isolation openings 23c along the first direction X. By providing the second sub-opening 24b between the third isolation openings 23c, the light transmittance between the third light emitting units 31c may be increased.

The first isolation opening 23a and the second isolation opening 23b are arranged along the second direction Y, and the second sub-opening 24b is located between the first isolation opening 23a and the second isolation opening 23b that are arranged along the second direction Y. The touch wiring 41 is distributed between the second sub-opening 24b and the first isolation opening 23a and between the second sub-opening 24b and the second isolation opening 23b, and the touch wiring 41 is not distributed between the second sub-opening 24b and the third light emitting unit 31c adjacent to the second sub-opening 24b, which is beneficial to increase the length of the third isolation opening 23c along the first direction X, and increase the size or distribution density of the third light emitting unit 31c.

Optionally, the projection area of the third isolation opening 23c on the array substrate 1 is less than the projection area of the first isolation opening 23a on the array substrate 1, and less than the projection area of the second isolation opening 23b on the array substrate 1, so that the projection area of the third light emitting unit 31c located in the third isolation opening 23c on the array substrate 1 is less than the projection area of the first light emitting unit 31a located in the first isolation opening 23a on the array substrate 1, and less than the projection area of the second light emitting unit 31b located in the second isolation opening 23b on the array substrate 1. Further, the touch wiring 41 is distributed between the second sub-opening 24b and the first isolation opening 23a, and between the second sub-opening 24b and the second isolation opening 23b, and the touch wiring 41 is not distributed between the second sub-opening 24b and the third light emitting unit 31c adjacent to the second sub-opening 24b. Therefore, compared to the first light emitting unit 31a and the second light emitting unit 31b, the third light emitting unit 31c has a larger light emitting angle, which is advantageous to increase the light emitting rate of the third light emitting unit 31c.

The embodiments of a fourth aspect of the present application further provides a display panel. Please refer to FIG. 1 to FIG. 23 again, the display panel includes an array substrate 1, a light emitting function layer and a touch layer 4; the light emitting function layer includes a plurality of light emitting units 31, at least a part of the light emitting unit 31 is disposed within the isolation opening 23; the touch layer 4 is disposed on a side of the isolation structure 2 away from the array substrate 1, the touch layer 4 includes a plurality of touch wirings 41, an orthographic projection of the touch wiring 41 on the array substrate 1 is located within an orthographic projection of the isolation structure 2 on the array substrate 1, the touch wirings 41 enclose and form a plurality of meshes 42, a mesh region corresponding to at least one of the meshes 42 includes a light emitting region A1 and a light transmission region A2, and the light emitting region A1 is provided with the light emitting unit 31.

The array substrate 1, the light emitting function layer and the touch layer 4 provided in the fourth aspect may be referred to the arrangement of the array substrate 1, the light emitting function layer and the touch layer 4 provided in the first aspect, which will not be repeated here.

The light emitting region A1 may emit light by setting the aforementioned isolation opening 23, and the light transmission region A2 may realize light transmission by setting the aforementioned first opening 24. It can also be achieved by increasing the light transmittance of the material for preparing the film layers in the light transmission region A2.

In the embodiments provided by the present application, by setting the light transmission region A2, the light transmittance of the display panel may be improved; by setting the light emitting region A1 and the light transmission region A2 in the corresponding mesh region of at least one mesh 42, the light transmittance of the corresponding region of the mesh 42 is improved.

In some embodiments, the display panel includes an isolation structure 2 disposed on a side of the array substrate 1, the isolation structure 2 is provided with a plurality of isolation openings 23 and a plurality of first openings 24, at least a part of the light emitting unit 31 is disposed within the isolation opening 23, and the first opening 24 located in the light transmission region A2.

The isolation structure 2 provided by the fourth aspect may be referred to the arrangement of the isolation structure 2 provided by the first aspect, which will not be repeated here.

By providing the first opening 24 in the light transmission region A2, the light transmittance of the light transmission region A2 is increased.

Optionally, by setting the orthographic projection of the touch wiring 41 on the array substrate 1 as being located within the orthographic projection of the isolation structure 2 on the array substrate 1, the problem that the touch layer 4 blocks the light entering the first openings 24 or blocks the light exiting the light emitting unit 31 may be avoided or reduced, and the light transmittance of the display panel may be improved.

The embodiments of a fifth aspect of the present application further provides a display panel. Please refer to FIG. 1 to FIG. 23 again, the display panel includes an array substrate 1, an isolation structure 2, a light emitting function layer and a touch layer 4. The isolation structure 2 is disposed on a side of the array substrate 1, and the isolation structure 2 is provided with a plurality of isolation openings 23 and a plurality of first openings 24; the light emitting function layer includes a plurality of light emitting units 31, at least a part of the light emitting unit 31 is disposed within the isolation opening 23; the touch layer 4 is disposed on a side of the isolation structure 2 away from the array substrate 1, the touch layer 4 includes a plurality of touch wirings 41, an orthographic projection of the touch wiring 41 on the array substrate 1 is located within an orthographic projection of the isolation structure 2 on the array substrate 1, and the light transmittance of the display panel is greater than or equal to 0.5%.

The array substrate 1, the isolation structure 2, the light emitting function layer and the touch layer 4 provided in the fifth aspect may be referred to the arrangement of the array substrate 1, the isolation structure 2, the light emitting function layer and the touch layer 4 provided in the first aspect, which will not be repeated here.

In the embodiments provided by the present application, by setting the first openings 24, the light transmittance of the display panel may be improved; by setting the orthographic projection of the touch wiring 41 on the array substrate 1 as being located within the orthographic projection of the isolation structure 2 on the array substrate 1, the problem that the touch layer 4 blocks the light entering the first openings 24 or blocks the light exiting the isolation openings 23 may be avoided or reduced, and the light transmittance of the display panel may be improved; by adjusting the position of the touch wiring 41, the light transmittance of the display panel may be set as being greater than or equal to 0.5%, which is beneficial to provide the light sensor on one side of the display panel.

The display panel includes a first display region and a second display region, the plurality of light emitting units are located in the first display region and the second display region, the plurality of first openings are located in the first display region, and the light transmittance of the display panel in the first display region is greater than or equal to 0.5%.

The embodiments of a sixth aspect of the present application further provides a display device including the display panel of any embodiment of the first aspect, the second aspect, the third aspect, the fourth aspect and the fifth aspect. Since the display device provided by the embodiments of the sixth aspect of the present application includes the display panel of any embodiment of the first aspect, the second aspect, the third aspect, the fourth aspect and the fifth aspect, the display device provided by the embodiments of the sixth aspect of the present application has the beneficial effect of the display panel of any embodiment of the first aspect, the second aspect, the third aspect, the fourth aspect and the fifth aspect, which will not be repeated here.

The display device in the embodiments of the present application includes, but is not limited to, a mobile phone, a personal digital assistant (PDA), a tablet computer, an e-book, a TV set, an access control, a smart landline telephone, a console and other devices with display functions.

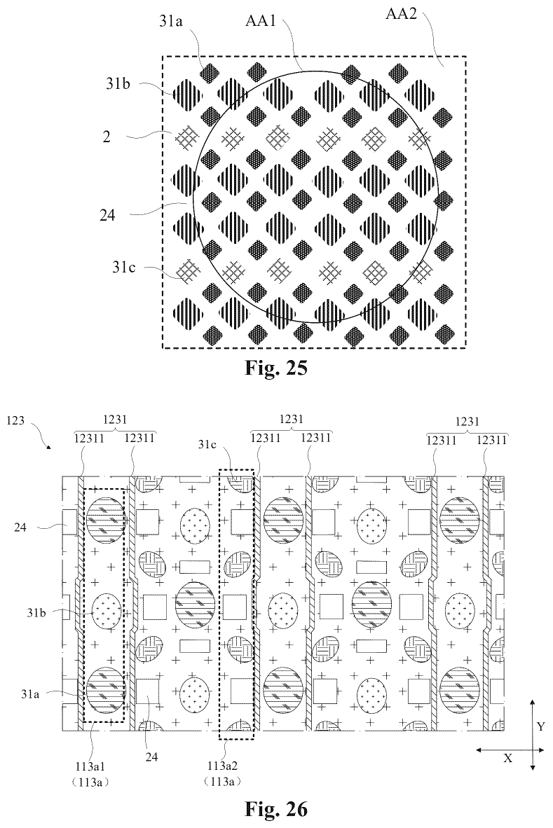

Referring to FIG. 24, FIG. 25 and FIG. 26, the embodiments of the present application provide a display module 10 including a display panel 100, a plurality of first openings 24, and a plurality of touch electrode portions 123. The display panel 100 has a display region AA, and the display region AA has a first display region AA1. The plurality of first openings 24 are spaced apart in the display panel 100 and located in the first display region AA1. The plurality of touch electrode portions 123 are disposed on the light emitting side of the display panel 100 and located in the first display region AA1; the orthographic projection of the touch electrode portion 123 on the display panel 100 is misplaced with the first opening 24, that is, the orthographic projection of the touch electrode portion 123 on the display panel 100 does not overlap with the first opening 24.

Here, the plurality of touch electrode portions 123 are spaced apart along the first direction X; each touch electrode portion 123 includes a plurality of touch sub-patterns 1231 spaced apart along the first direction X, each touch sub-pattern 1231 extends along the second direction Y; the first direction X intersects the second direction Y; at least a part of the first opening 24 is located between two adjacent touch sub-patterns 1231.

It may be understood that the display panel 100 may include an array substrate 1, a light emitting unit and an encapsulation layer (not shown) that are stacked. The first display region AA1 is equivalent to a light transmission region, and there may be one first display region AA1 or a plurality of first display regions AA1; meanwhile, the display region AA is further provided with a second display region AA2, and the second display region AA2 is equivalent to a light opaque display region. The plurality of touch electrode portions 123 may include a plurality of first touch electrode portions and a plurality of second touch electrode portions, here, the first touch electrode portion may be a RX electrode and the second touch electrode portion may be a TX electrode. Further, the second display region AA2 is provided with a plurality of first touch electrodes used as RX electrodes and a plurality of second touch electrodes used as TX electrodes, the first touch electrode portion is electrically connected to a corresponding first touch electrode, and the second touch electrode portion is electrically connected to a corresponding second touch electrode. Exemplarily, the display module 10 includes a touch layer 4 including a touch electrode portion 123, a first touch electrode, and a second touch electrode. The touch electrode portion 123 may also be a touch wiring 41, and the touch sub-pattern 1231 may be enclosed and formed by a portion of the touch wiring 41.

In the embodiments of the present application, the touch sub-pattern 1231 extends along the second direction Y, which is equivalent to form the shape of the touch sub-pattern 1231 as a strip. By setting that each touch electrode portion 123 includes a plurality of touch sub-patterns 1231 spaced apart along the first direction X, it is equivalent to forming a region having no touch pattern between two adjacent touch sub-patterns 1231, so that compared with the arrangement mode of touch pattern layout being relatively dense in the traditional technology, the embodiments of the present application is beneficial to reduce the pattern density of the touch electrode portions 123. Further, since at least a part of the first opening 24 is located between the two adjacent touch sub-patterns 1231, the touch sub-pattern 1231 must not surround a part of the periphery of the first opening 24. Compared with the arrangement mode of setting the touch pattern as surrounding the full periphery of the first opening 24 in the traditional technology, the pattern density of the touch electrode at the periphery of the first opening 24 is reduced, thereby reducing the possibility of the radio frequency interference or signal crosstalk between the touch electrode portion 123 in the first display region AA1 and the signal wiring 121 in the display panel 100 through the first opening 24, and improving the use performance of the display module 10.

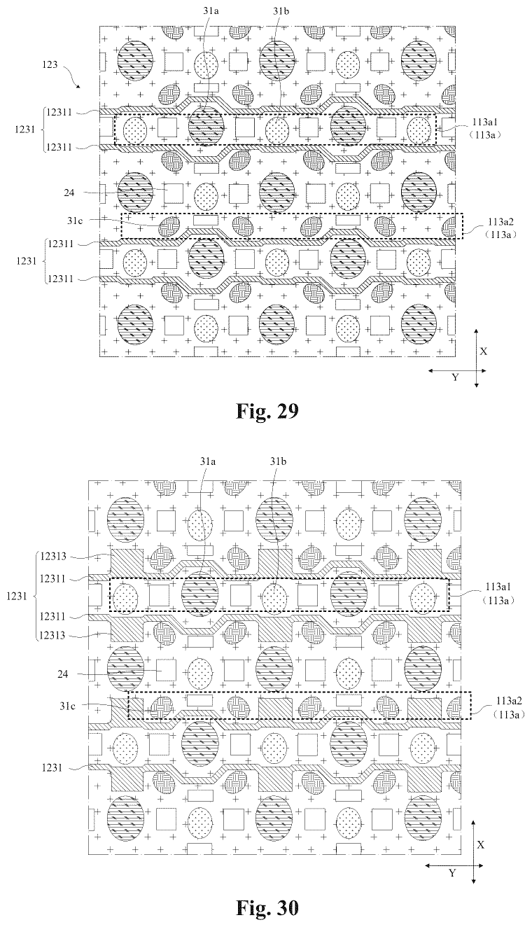

It should be noted that in the embodiments of the present application, FIG. 26 to FIG. 30 and FIG. 17 are local schematic diagrams of one touch electrode portion 123.

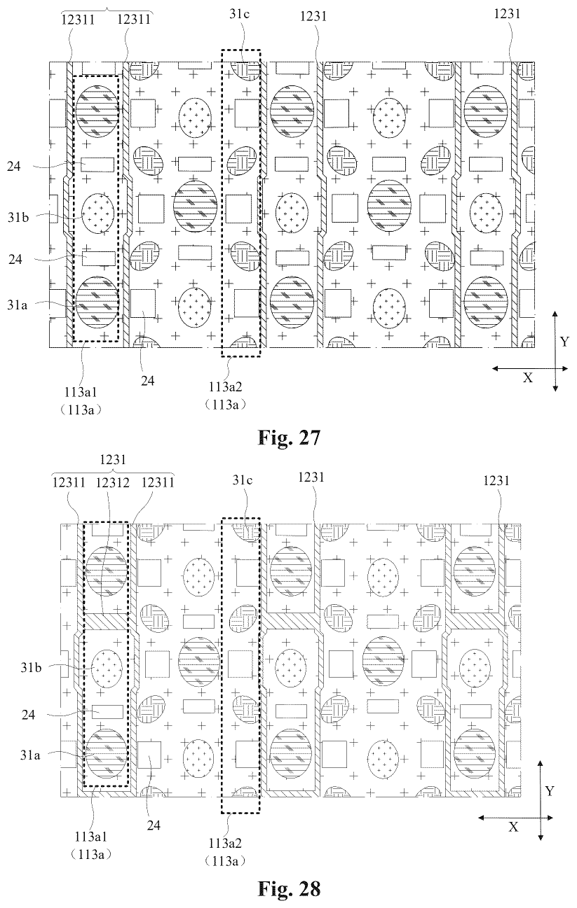

In one embodiment, referring to FIG. 26 and FIG. 27, the display panel 100 includes a plurality of pixel lines 113a, the plurality of pixel lines 113a are spaced apart in the first display region AA1 along the first direction X, and each pixel line 113a includes a plurality of light emitting units spaced apart along the second direction Y 1. At least one pixel line 113a is provided between the two adjacent touch sub-patterns 1231, here, in a same pixel line 113a provided between the two adjacent touch sub-patterns 1231, a first opening 24 is provided between two adjacent light emitting units of at least a part of the light emitting units. It should be understood that the pixel line 113a can be a pixel row or a pixel column. Thus, it is advantageous to arrange the first opening 24 and the touch sub-pattern 1231, thereby reducing the possibility of the radio frequency interference or signal crosstalk between the touch electrode portion 123 in the first display region AA1 and the signal wiring 121 in the display panel 100 through the first opening 24.

It should be noted that when a plurality of pixel lines 113a are provided between the two touch sub-patterns 1231, only one pixel line 113a in the plurality of pixel lines 113a may be provided with the first opening 24, and in the pixel line 113a, the first opening 24 may be provided between two adjacent light emitting units 31 of at least a part of the light emitting units 31, or the first opening 24 may be provided between any two adjacent light emitting units 31. Further, in the plurality of pixel lines 113a, each pixel line 113a may be provided with the first opening 24, and in each pixel line 113a, the first opening 24 may be provided between two adjacent light emitting units 31 of at least a part of the light emitting units 31, or the first opening 24 may be provided between any two adjacent light emitting units.

In one embodiment, each touch sub-pattern 1231 surrounds the periphery of at least one pixel line 113a. Therefore, on the one hand, it is beneficial to fully utilize the arrangement space on the display panel 100, and on the other hand, it is beneficial to reduce the influence of the touch sub-pattern 1231 on the light emitting of the display panel 100.

In one embodiment, referring to FIG. 26 and FIG. 27, the touch sub-pattern 1231 includes two first wiring portions 12311 spaced apart along the first direction X, and each first wiring portion 12311 extends along the second direction Y. Here, the first wiring portion 12311 is equivalent to a strip wiring. Thus, the pattern structure of the touch sub-pattern 1231 is relatively simple, so as to not only facilitate the arrangement, but also reduce the pattern density of the touch electrode portions 123.

In one embodiment, in a same touch sub-pattern 1231, a pixel line 113a is provided between the two first wiring portions 12311. Thus, the touch sub-pattern 1231 occupies less space, so as to provide more touch sub-patterns 1231 in a limited area, thereby increasing the capacity value of the touch electrode portion 123, reducing the impedance of the touch electrode portion 123, and thus improving the touch control performance.

In one embodiment, in a same touch sub-pattern 1231, the pixel line 113a located between the two first wiring portions 12311 has a first center line (not shown) parallel to the second direction Y, and the touch sub-pattern 1231 is symmetrically arranged with respect to the first center line. Thus, it is advantageous to keep the touch sub-pattern 1231 and the light emitting unit 31 in the pixel line 113a symmetrical, thus improving the problem of visual angle and color bias caused by the touch sub-pattern 1231 being an asymmetric structure.

In one embodiment, the touch sub-patterns 1231 in the same touch electrode portion 123 are uniformly arranged. This is beneficial to improve the touch performance and display effect.

In one embodiment, referring to FIG. 26, all of the first openings 24 are located between the two adjacent touch sub-patterns 1231. That is, the first opening 24 is not provided between the two first wiring portions 12311 of the same touch sub-pattern 1231. Therefore, the possibility of the radio frequency interference or signal crosstalk between the touch electrode portion 123 and the signal wiring 121 in the display panel 100 through the first opening 24 may be reduced.

In one embodiment, referring to FIG. 27 and FIG. 28, the first opening 24 includes a first first opening and a second first opening, the first first opening is provided between the two adjacent touch sub-patterns 1231, and the second first opening is provided between the two first wiring portions 12311 of the same touch sub-pattern 1231. Thus, the first opening 24 is provided between the adjacent touch sub-patterns 1231, and the first opening 24 is provided between the two first wiring portions 12311 of the same touch sub-pattern 1231, which is beneficial to improve the light transmission performance of the light transmission region, and improve the service performance of the device under the screen.

In one embodiment, referring to FIG. 28, the touch sub-pattern 1231 further includes a first compensation portion 12312 disposed between the two first wiring portions 12311 and electrically connecting the two first wiring portions 12311. By setting the first compensation portion 12312, the decrease of the touch capacity value caused by the decrease of the pattern density of the touch electrode portion 123 may be compensated, which is beneficial to improve the touch control performance.

In one embodiment, referring to FIG. 26 to FIG. 29, the plurality of pixel lines 113a include a plurality of first pixel lines 113a1 and a plurality of second pixel lines 113a2, the plurality of first pixel lines 113a1 and the plurality of second pixel lines 113a2 are arranged alternately along the first direction X; the first pixel line 113a1 includes a plurality of first light emitting units 31a and a plurality of second light emitting units 31b that are arranged alternately along the second direction Y; the second pixel line 113a2 includes a plurality of third light emitting units 31c spaced apart along the second direction Y interval; the periphery of a part of the first pixel lines 113a1 is provided with a touch sub-pattern 1231, that is, in all of the first pixel lines 113a1, the periphery of some of the first pixel lines 113a1 is provided with a touch sub-pattern 1231. Thus, it is beneficial to reduce the pattern density of the touch electrode portion 123.

It is understood that, in the drawings shown in FIG. 26 to FIG. 28, the pixel line 113a is the pixel column. In the drawing shown in FIG. 10, the pixel line 113a is the pixel row.

In one embodiment, one first pixel line 113a1 and two second pixel lines 113a2 are provided between two adjacent touch sub-patterns 1231.

Further, referring to FIG. 26, in a same second pixel line 113a2, the first opening 24 is provided between two adjacent third light emitting units 31c of at least a part of the third light emitting units 31c. Thus, the touch sub-pattern 1231 is provided at only one side of the periphery of the first opening 24 in the second pixel line 113a2, which helps to reduce the pattern density of the touch electrode at the periphery of the first opening 24, thus reducing the possibility of the radio frequency interference or signal crosstalk.

In one embodiment, in the first pixel line 113a1 between the two adjacent touch sub-patterns 1231, the first opening 24 is provided between the adjacent first light emitting unit 31a and the second light emitting unit 321 b. In this way, it is beneficial to further improve the transmittance performance of the light transmittance region.

In one embodiment, referring to FIG. 27, in a same first pixel line 113a1, the first opening 24 is provided between the adjacent first light emitting unit 31a and the second light emitting unit 31b. That is, the first opening 24 is provided in any first pixel line 113a1, and in the same first pixel line 113a1, the first opening 24 is provided between the adjacent first light emitting unit 31a and the second light emitting unit 31b. In this way, it is beneficial to further improve the transmittance performance of the light transmittance region.

In one embodiment, referring to FIG. 30, the touch sub-pattern 1231 further includes a second compensation portion 12313, at least one of the first wiring portions 12311 is provided with the second compensation portion 12313, and the second compensation portion 12313 is disposed on a side of the first wiring portion 12311 away from another first wiring portion 12311. By setting the second compensation portion 12313, the decrease of the touch capacity value caused by the decrease of the pattern density of the touch electrode portion 123 may be compensated, which is beneficial to improve the touch control performance.

In one embodiment, the second compensation portion 12313 may be provided at the side of one of the two first wiring portions 12311 away from the other of the two first wiring portions 12311, as well as the side of the other of the two first wiring portions 12311 away from of the one of the two first wiring portions 12311. Specifically, as shown in FIG. 30, in the first pixel line 113a1, the first opening 24 is provided between the adjacent first light emitting unit 31a and the second light emitting unit 31b. In the second pixel line 113a2, the first opening 24 is provided between two adjacent third light emitting units 31c of a part of the third light emitting units 31c, the first opening 24 is not provided between two adjacent third light emitting units 31c of another part of the third light emitting units 31c, and the second compensation portion 12313 is provided between the two adjacent third light emitting units 31c of the another part of the third light emitting units 31c.

Thus, on the one hand, it is beneficial to further improve the touch control performance. On the other hand, since the second compensation portion 12313 is far from the first opening 24, it does not increase the radio frequency interference while increasing the pattern density.

In one embodiment, the display module 10 further includes a bridging layer 13, the bridging layer 13 is disposed on a side of the touch layer 4 away from the array substrate 1, and is used for electrically connecting two adjacent first touch electrodes (or second touch electrodes).

Referring to FIG. 24 to FIG. 31, the embodiments of the present application provide a display module 10 including a display panel 100, a plurality of first openings 24, and a plurality of touch electrode portions 123. The display panel 100 has a display region AA, and the display region AA has a first display region AA1. The plurality of first openings 24 are spaced apart from each other in the first display region AA1 of the display panel 100. The plurality of touch electrode portions 123 are disposed on the light emitting side of the display panel 100 and located in the first display region AA1. Each touch electrode portion 123 includes at least one touch sub-pattern 1231. Here, the orthographic projection of the touch sub-pattern 1231 on the display panel 100 is misplaced with the first opening 24, and the orthographic projection surrounds a part of the periphery of at least a part of the first openings 24.

It may be understood that the display panel 100 may include an array substrate 1, a light emitting unit and an encapsulation layer that are stacked. The first display region AA1 is equivalent to a light transmission region, and there may be one first display region AA1 or a plurality of first display regions AA1; meanwhile, the display region AA is further provided with a second display region AA2, and the second display region AA2 is equivalent to a light opaque display region. The plurality of touch electrode portions 123 may include a plurality of first touch electrode portions and a plurality of second touch electrode portions, here, the first touch electrode portion may be a RX electrode and the second touch electrode portion may be a TX electrode. Further, the second display region AA2 is provided with a plurality of first touch electrodes used as RX electrodes and a plurality of second touch electrodes used as TX electrodes, the first touch electrode portion is electrically connected to a corresponding first touch electrode, and the second touch electrode portion is electrically connected to a corresponding second touch electrode. Further, the display module 10 includes a touch layer 4 including a touch electrode portion 123, a first touch electrode, and a second touch electrode.

For the display module 10 provided by the embodiments of the present application, the touch electrode portion 123 include at least one touch sub-pattern 1231, and the orthographic projection of the touch sub-pattern 1231 on the display panel 100 is misplaced with the first opening 24, and surrounds a part of the periphery of at least a part of the first openings 24. Thus, compared with the arrangement mode of setting the touch pattern as surrounding the full periphery of the first opening 24 in the traditional technology, in the embodiments of the present application, the touch sub-pattern 1231 must not surround a part of the periphery of at least a part of the first openings 24, thus reducing the pattern density of the touch electrode at the periphery of the first opening 24, thereby reducing the possibility of the radio frequency interference or signal crosstalk between the touch electrode portion 123 in the first display region AA1 and the signal wiring 121 in the display panel 100 through the first opening 24, and improving the use performance of the display module 10.

In one embodiment, as shown in FIG. 26, each touch electrode portion 123 includes a plurality of touch sub-patterns 1231 spaced apart along the first direction X, each touch sub-pattern 1231 extends along the second direction Y; the first direction X intersects the second direction Y; at least a part of the first opening 24 is located between two adjacent touch sub-patterns 1231.

In the embodiments of the present application, the touch sub-pattern 1231 extends along the second direction Y, which is equivalent to form the shape of the touch sub-pattern 1231 as a strip. By setting that each touch electrode portion 123 includes a plurality of touch sub-patterns 1231 spaced apart along the first direction X, it is equivalent to forming a region having no touch pattern between two adjacent touch sub-patterns 1231, so that compared with the arrangement mode of touch pattern layout being relatively dense in the traditional technology, the embodiments of the present application is beneficial to reduce the pattern density of the touch electrode portions 123.

In one embodiment, referring to FIG. 26 and FIG. 27, the display panel 100 includes a plurality of pixel lines 113a, the plurality of pixel lines 113a are spaced apart in the first display region AA1 along the first direction X, and each pixel line 113a includes a plurality of light emitting units spaced apart along the second direction Y 1. At least one pixel line 113a is provided between the two adjacent touch sub-patterns 1231, here, in a same pixel line 113a provided between the two adjacent touch sub-patterns 1231, a first opening 24 is provided between two adjacent light emitting units of at least a part of the light emitting units. It should be understood that the pixel line 113a can be a pixel row or a pixel column. Thus, it is advantageous to arrange the first opening 24 and the touch sub-pattern 1231, thereby reducing the possibility of the radio frequency interference or signal crosstalk between the touch electrode portion 123 in the first display region AA1 and the signal wiring 121 in the display panel 100 through the first opening 24.

It should be noted that when a plurality of pixel lines 113a are provided between the two touch sub-patterns 1231, only one pixel line 113a in the plurality of pixel lines 113a may be provided with the first opening 24, and in the pixel line 113a, the first opening 24 may be provided between two adjacent light emitting units of at least a part of the light emitting units, or the first opening 24 may be provided between any two adjacent light emitting units. Further, in the plurality of pixel lines 113a, each pixel line 113a may be provided with the first opening 24, and in each pixel line 113a, the first opening 24 may be provided between two adjacent light emitting units 31 of at least a part of the light emitting units, or the first opening 24 may be provided between any two adjacent light emitting units.

In one embodiment, each touch sub-pattern 1231 surrounds the periphery of at least one pixel line 113a. Therefore, on the one hand, it is beneficial to fully utilize the arrangement space on the display panel 100, and on the other hand, it is beneficial to reduce the influence of the touch sub-pattern 1231 on the light emitting of the display panel 100.

In one embodiment, the touch sub-pattern 1231 includes two first wiring portions 12311 spaced apart along the first direction X, and each first wiring portion 12311 extends along the second direction Y. Here, the first wiring portion 12311 is equivalent to a strip wiring. Thus, the pattern structure of the touch sub-pattern 1231 is relatively simple, so as to not only facilitate the arrangement, but also reduce the pattern density of the touch electrode portions 123.

In one embodiment, in a same touch sub-pattern 1231, a pixel line 113a is provided between the two first wiring portions 12311. Thus, the touch sub-pattern 1231 occupies less space, so as to provide more touch sub-patterns 1231 in a limited area, thereby increasing the capacity value of the touch electrode portion 123, reducing the impedance of the touch electrode portion 123, and thus improving the touch control performance.

In one embodiment, in a same touch sub-pattern 1231, the pixel line 113a located between the two first wiring portions 12311 has a first center line (not shown) parallel to the second direction Y, and the touch sub-pattern 1231 is symmetrically arranged with respect to the first center line. Thus, it is advantageous to keep the touch sub-pattern 1231 and the light emitting unit in the pixel line 113a symmetrical, thus improving the problem of visual angle and color bias caused by the touch sub-pattern 1231 being an asymmetric structure.

In one embodiment, referring to FIG. 26, all of the first openings 24 are located between the two adjacent touch sub-patterns 1231. That is, the first opening 24 is not provided between the two first wiring portions 12311 of the same touch sub-pattern 1231. Therefore, the possibility of the radio frequency interference or signal crosstalk between the touch electrode portion 123 and the signal wiring 121 in the display panel 100 through the first opening 24 may be reduced.

In one embodiment, the first opening 24 includes a first first opening and a second first opening, the first first opening is provided between the two adjacent touch sub-patterns 1231, and the second first opening is provided between the two first wiring portions 12311 of the same touch sub-pattern 1231. Thus, the first opening 24 is provided between the adjacent touch sub-patterns 1231, and the first opening 24 is provided between the two first wiring portions 12311 of the same touch sub-pattern 1231, which is beneficial to improve the light transmission performance of the light transmission region, and improve the service performance of the device under the screen.

In one embodiment, referring to FIG. 28, the touch sub-pattern 1231 further includes a first compensation portion 12312 disposed between the two first wiring portions 12311 and electrically connecting the two first wiring portions 12311. By setting the first compensation portion 12312, the decrease of the touch capacity value caused by the decrease of the pattern density of the touch electrode portion 123 may be compensated, which is beneficial to improve the touch control performance.

In one embodiment, referring to FIG. 30, the touch sub-pattern 1231 further includes a second compensation portion 12313, at least one of the first wiring portions 12311 is provided with the second compensation portion 12313, and the second compensation portion 12313 is disposed on a side of the first wiring portion 12311 away from another first wiring portion 12311. By setting the second compensation portion 12313, the decrease of the touch capacity value caused by the decrease of the pattern density of the touch electrode portion 123 may be compensated, which is beneficial to improve the touch control performance.

In one embodiment, the second compensation portion 12313 may be provided at the side of one of the two first wiring portions 12311 away from the other of the two first wiring portions 12311, as well as the side of the other of the two first wiring portions 12311 away from of the one of the two first wiring portions 12311.

Specifically, as shown in FIG. 30, in the first pixel line 113a1, the first opening 24 is provided between the adjacent first light emitting unit 31a and the second light emitting unit 31b. In the second pixel line 113a2, the first opening 24 is provided between two adjacent third light emitting units 31c of a part of the third light emitting units 31c, the first opening 24 is not provided between two adjacent third light emitting units 31c of another part of the third light emitting units 31c, and the second compensation portion 12313 is provided between the two adjacent third light emitting units 31c of the another part of the third light emitting units 31c.

Thus, on the one hand, it is beneficial to further improve the touch control performance. On the other hand, since the second compensation portion 12313 is far from the first opening 24, it does not increase the radio frequency interference while increasing the pattern density.

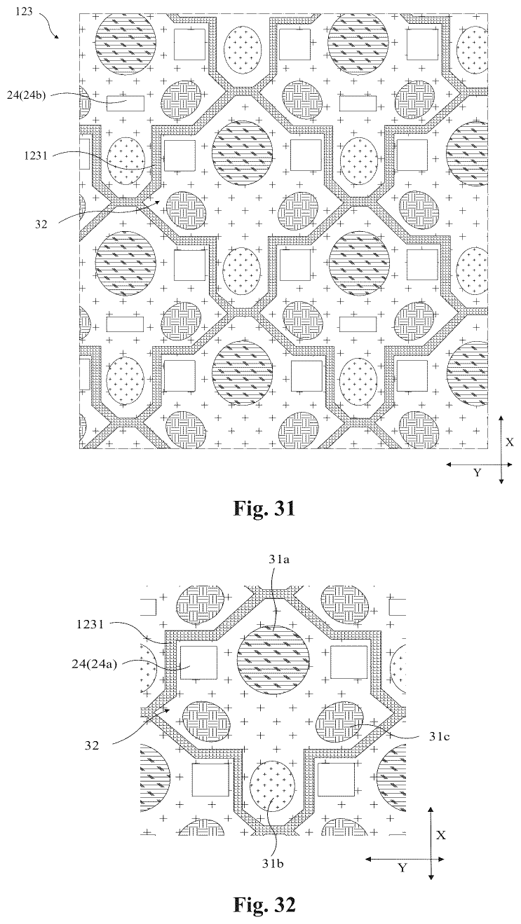

In one embodiment, referring to FIG. 31 and FIG. 32, the display panel 100 includes a plurality of pixel light emitting groups 32, each pixel light emitting group 32 is provided with at least one first opening 24; the orthographic projection of the touch sub-pattern 1231 on the display panel 100 surrounds the periphery of the pixel light emitting group 32. Thus, the touch sub-pattern 1231 is set as surrounding the pixel light emitting group 32, which is beneficial to reduce the pattern density of the touch pattern portion.

In one embodiment, the pixel light emitting group 32 includes one first light emitting unit 31a, one second light emitting unit 31b, and two third light emitting units 31c; in a same pixel light emitting group 32, the first light emitting unit 31a, the second light emitting unit 31b, and the third light emitting units 31c form a virtual quadrangle.

In one embodiment, the plurality of pixel light emitting groups 32 are arranged in rows along the first direction X and arranged in columns along the second direction Y intersecting the first direction X. In a same pixel light emitting group 32, the first light emitting unit 31a and the second light emitting unit 31b are spaced apart along the second direction Y, and the two third light emitting units 31c are spaced apart along the first direction X. The pixel light emitting group 32 is provided with two first openings 24a, the two first openings 24a are disposed on two opposite sides of the first light emitting unit 31a along the first direction X. Such, on the one hand, it is beneficial to ensure that the transmittance region has good transmittance performance, and on the other hand, it is beneficial to reduce the possibility of the radio frequency interference and signal crosstalk.

In one embodiment, the pixel light emitting group 32 is also provided with a second first opening 24b, and the second first opening 24b is provided between the two third light emitting units 31c. In this way, the light transmittance performance of the light transmittance region can be further improved.

In one embodiment, the two adjacent touch sub-patterns 1231 share a common side. This is beneficial to reduce the pattern density of the touch pattern portion.

The above embodiments only express several embodiments of the present application, which are specific and detailed, but cannot be understood as a limitation on the scope of patent application. It should be noted that for those skilled in the art, several changes and improvements can be made without departing from the conception of the present application, which fall within the protection scope of the present application. Therefore, the protection scope of the present patent application is defined only by the scope of the appended claims.

According to the above embodiments of the present application, these embodiments do not describe all the details and do not limit the present application to the specific embodiments. Obviously, according to the above description, many modifications and changes can be made. This specification selects and describes these embodiments in order to better explain the principle and practical application of the present application, so that those skilled in the art can make good use of the present application and can make modification of the present application. The present application is limited only by the claims and the equivalents thereof.

What is claimed is:

1. A display panel, comprising:
an array substrate;
an isolation structure disposed on a side of the array substrate, the isolation structure being provided with a plurality of isolation openings and a plurality of first openings;
a light emitting function layer comprising a plurality of light emitting units, at least a part of the light emitting unit being disposed within the isolation opening;
a touch layer disposed on a side of the isolation structure away from the array substrate, the touch layer comprising one or more touch wirings, an orthographic projection of the touch wiring on the array substrate being located within an orthographic projection of the isolation structure on the array substrate, an orthographic projection of the touch wiring on the isolation structure being a first projection, and the first projection surrounding a part of a boundary of at least one of the first openings.

2. The display panel of claim 1, wherein the first projection does not surround another part of the boundary of the at least one of the first openings;
the first opening is located between adjacent isolation openings, and the first projection is not distributed between a part of a boundary of the first opening and the isolation opening.

3. The display panel of claim 1, wherein a shape of an orthographic projection of the first opening on the array substrate is a polygon, and the first opening comprises a plurality of boundary lines; the first opening and the touch wiring satisfy at least one of:
the first projection being not distributed between a boundary line of the first opening and the isolation opening;
the first projection being not distributed between either one of two opposite boundary lines of the first opening and a corresponding isolation opening adjacent to the either one of the two opposite boundary lines of the first opening;
the first projection being not distributed between a plurality of contiguous boundary lines of the first opening and the isolation opening;
at least one of the first openings having symmetry relative to a first symmetry axis, and a boundary of the at least one of the first openings not surrounded by the first projection having symmetry relative to the first symmetry axis.

4. The display panel of claim 1, wherein the plurality of light emitting units comprise a first light emitting unit for emitting a first color light and a second light emitting unit for emitting a second color light, the plurality of isolation openings comprise a first isolation opening and a second isolation opening, at least a part of the first light emitting unit is located within the first isolation opening, and at least a part of the second light emitting unit is located within the second isolation opening;
the plurality of first openings comprise a plurality of first sub-openings, the first sub-opening is disposed between the first isolation opening and the second isolation opening adjacent to the first isolation opening in a first direction.

5. The display panel of claim 4, wherein the first opening comprises a plurality of boundary lines; a part of the first projection is distributed along a plurality of continuously connected boundary lines of the first sub-opening.

6. The display panel of claim 4, wherein the plurality of light emitting units further comprise a third light emitting unit for emitting a third color light, the plurality of isolation openings further comprise a third isolation opening, at least a part of the third light emitting unit is located in the third isolation opening; the plurality of first openings further comprise a plurality of second sub-openings, the second sub-opening is disposed between adjacent third isolation openings;
the plurality of the first sub-openings are arranged in rows along the first direction and form a plurality of rows of the first sub-openings; the plurality of the second sub-openings are arranged in rows along the first direction and form a plurality of rows of the second sub-openings, the second sub-opening and the first sub-opening are in different rows;
a part of the first projection is distributed along two opposite boundary lines of the second sub-opening.

7. The display panel of claim 4, wherein the first projection surrounds an entire boundary of the first isolation opening, at least a part of the first projection surrounds a part of a boundary of the second isolation opening, and another part of the second isolation opening is not surrounded by the first projection;
two opposite boundary lines of the second isolation opening are not surrounded by the first projection.

8. The display panel of claim 1, wherein
the touch wirings enclose and form a plurality of meshes, the plurality of meshes correspond to a plurality of mesh regions in a one to one relationship, at least one of the mesh regions is provided with the isolation opening and the first opening adjacent to the isolation opening;
the touch wirings enclosing and forming two adjacent meshes have a common touch wiring;
at least one of the meshes has symmetry.

9. The display panel of claim 8, wherein the plurality of isolation openings comprise a first isolation opening, the plurality of the light emitting units comprise a first light emitting unit for emitting a first color light, at least a part of the first light emitting unit is located within the first isolation opening; an orthographic projection of the touch wirings enclosing and forming at least one of the meshes on the isolation structure surrounds an entire boundary of the first isolation opening;
the plurality of isolation openings comprise a second isolation opening, the plurality of light emitting units comprise a second light emitting unit for emitting a second color light, at least a part of the second light emitting unit is located within the second isolation opening, and at least one of the mesh regions is provided with the second isolation opening and the first openings on two opposite sides of the second isolation opening;
in a same mesh region, the first projection is not distributed between the second isolation opening and the first opening adjacent to the second isolation opening;
the second isolation opening has symmetry relative to a second symmetry axis, and a boundary of the second isolation opening not surrounded by the first projection has symmetry relative to the second symmetry axis;
the plurality of the isolation openings comprise a third isolation opening, the plurality of light emitting units comprise a third light emitting unit for emitting a third color light, at least a part of the third light emitting unit is located in the third isolation opening; and at least one of the mesh regions is provided with the first opening and third isolation openings on two opposite sides of the first opening;
in a same mesh region, the first projection is not distributed between the third isolation opening and the first opening adjacent to the third isolation opening.

10. The display panel of claim 8, wherein one of the mesh regions is provided with one first light emitting unit, one second light emitting unit and two third light emitting units; in a same mesh region, center points of the first light emitting unit, the second light emitting unit and the third light emitting units are connected to form a virtual quadrilateral;
the plurality of mesh regions are arranged in rows along a first direction and arranged in columns along a second direction intersecting the first direction; in a same mesh region, the first light emitting unit and the second light emitting unit are spaced along the second direction, and the two third light emitting units are spaced along the first direction;
in a same mesh region, two first openings are disposed on two opposite sides of the first light emitting unit along the first direction, and/or two first openings are disposed on two opposite sides of the second light emitting unit along the first direction, and/or at least one first opening is disposed between the two third light emitting units.

11. The display panel of claim 1, wherein the plurality of first openings comprise a third sub-opening and a fourth sub-opening, the first projection surrounds a part of a boundary of the third sub-opening, a part of the first projection does not surround another part of the boundary of the third sub-opening, a part of the first projection surrounds an entire boundary of the fourth sub-opening, a projection area of the third sub-opening on the array substrate is greater than a projection area of the fourth sub-opening on the array substrate;
the third sub-opening and the fourth sub-opening both comprise a boundary line extending along a first direction and a boundary line extending along a second direction, the first projection does not surround the boundary line of the third sub-opening extending along the second direction, a length of the third sub-opening along the first direction is greater than a length of the fourth sub-opening along the first direction, and the first direction intersects the second direction.

12. The display panel of claim 1, wherein the first opening comprises a first boundary line and a second boundary line, and at least a part of the first projection is located between the first boundary line and the isolation opening, and the first projection is not located between the second boundary line and the isolation opening;
a minimum distance of the first boundary line to a boundary of the isolation opening adjacent to the first boundary line is greater than a minimum distance of the second boundary line to a boundary of the isolation opening adjacent to the second boundary line;
the minimum distance of the first boundary line to the boundary of the isolation opening adjacent to the first boundary line is greater than or equal to 11 um, and the minimum distance of the second boundary line to the boundary of the isolation opening adjacent to the second boundary line is greater than or equal to 5.5 um.

13. The display panel of claim 1, wherein the isolation openings comprise a fourth isolation opening and a fifth isolation opening, a light emitting color of the light emitting unit in the fourth isolation opening is the same as or different from a light emitting color of the light emitting unit in the fifth isolation opening, and a minimum distance from a boundary of the fourth isolation opening to the touch wiring is the same as a minimum distance from a boundary of the fifth isolation opening to the touch wiring.

14. The display panel of claim 1, wherein at least a part of the first projection surrounds a third boundary line and a fourth boundary line of the first opening, and a minimum distance of the first projection to the third boundary line is not the same as a minimum distance of the first projection to the fourth boundary line.

15. The display panel of claim 1, wherein the display panel comprises a first display region and a second display region, and the plurality of first openings are distributed in the first display region;
a light transmittance of the first display region is greater than or equal to 0.5%;
wherein
a pixel arrangement of the light emitting units in the second display region is the same as a pixel arrangement of the light emitting units the first display region;
a pattern of the touch wirings located in the second display region is the same as a pattern of the touch wirings located in the first display region; or
a distribution density of the touch wirings in the first display region is less than a distribution density of the touch wirings in the second display region.

16. A display panel, comprising:
an array substrate;
an isolation structure disposed on a side of the array substrate, the isolation structure enclosing and forming a plurality of isolation openings, and the isolation structure being provided with a plurality of first openings;
a light emitting function layer comprising a plurality of light emitting units, at least a part of the light emitting unit being disposed within the isolation opening;
a touch layer disposed on a side of the isolation structure away from the array substrate, the touch layer comprising one or more touch wirings, an orthographic projection of the touch wiring on the array substrate being located within an orthographic projection of the isolation structure on the array substrate, an orthographic projection of the touch wiring on the isolation structure being a first projection, and the first projection being not distributed between at least one isolation opening and the first opening adjacent to the at least one isolation opening.

17. The display panel of claim 16, wherein the plurality of light emitting units comprise a first light emitting unit for emitting a first color light and a second light emitting unit for emitting a second color light, the plurality of isolation openings comprise a first isolation opening and a second isolation opening, at least a part of the first light emitting unit is located within the first isolation opening, and at least a part of the second light emitting unit is located within the second isolation opening;
the plurality of first openings comprise a plurality of first sub-openings, the first sub-opening is disposed between the first isolation opening and the second isolation opening adjacent to the first isolation opening in a first direction;
the plurality of light emitting units further comprise a third light emitting unit for emitting a third color light, the plurality of isolation openings further comprise a third isolation opening, at least a part of the third light emitting unit is located in the third isolation opening; the plurality of first openings further comprise a plurality of second sub-openings, the second sub-opening is disposed between adjacent third isolation openings.

18. The display panel of claim 16, wherein the touch wirings enclose and form a plurality of meshes, the plurality of meshes correspond to a plurality of mesh regions in a one to one relationship, at least one of the mesh regions is provided with the isolation opening and the first opening adjacent to the isolation opening;
the touch wirings enclosing and forming two adjacent meshes have a common touch wiring;
the plurality of isolation openings comprise a first isolation opening, the plurality of the light emitting units comprise a first light emitting unit for emitting a first color light, at least a part of the first light emitting unit is located within the first isolation opening; an orthographic projection of the touch wirings enclosing and forming at least one of the meshes on the isolation structure surrounds an entire boundary of the first isolation opening;
the plurality of isolation openings comprise a second isolation opening, the plurality of light emitting units comprise a second light emitting unit for emitting a second color light, at least a part of the second light emitting unit is located within the second isolation opening, and at least one of the mesh regions is provided with the second isolation opening and the first openings on two opposite sides of the second isolation opening;
the plurality of the isolation openings comprise a third isolation opening, the plurality of light emitting units comprise a third light emitting unit for emitting a third color light, at least a part of the third light emitting unit is located in the third isolation opening; and at least one of the mesh regions is provided with the first opening and third isolation openings on two opposite sides of the first opening.

19. A display panel, comprising:
an array substrate;
an isolation structure disposed on a side of the array substrate, the isolation structure being provided with a plurality of isolation openings and a plurality of first openings;
a light emitting function layer comprising a plurality of light emitting units, at least a part of the light emitting unit being disposed within the isolation opening;
a touch layer disposed on a side of the isolation structure away from the array substrate, the touch layer comprising one or more touch wirings, the touch wirings enclosing and forming a plurality of meshes, and a mesh region corresponding to at least one of the meshes being provided with the isolation opening and the first opening.

20. The display panel of claim 19, wherein
the plurality of isolation openings comprise a second isolation opening, the plurality of light emitting units comprise a second light emitting unit for emitting a second color light, at least a part of the second light emitting unit is located within the second isolation opening, and the mesh region corresponding to at least one of the meshes is provided with the second isolation opening and the first openings on two opposite sides of the second isolation opening;
an orthographic projection of the touch wiring on the isolation structure is a first projection, and in the mesh region corresponding to a same mesh, the first projection is not distributed between the second isolation opening and the first opening adjacent to the second isolation opening;
the plurality of the isolation openings comprise a third isolation opening, the plurality of light emitting units comprise a third light emitting unit for emitting a third color light, at least a part of the third light emitting unit is located in the third isolation opening; and the mesh region corresponding to at least one of the meshes is provided with the first opening and third isolation openings on two opposite sides of the first opening;
the orthographic projection of the touch wiring on the isolation structure is the first projection, and in the mesh region corresponding to a same mesh, the first projection is not distributed between the third isolation opening and the first opening adjacent to the third isolation opening.
